(19) United States
(12) Patent Application Publication
(10) Pub. No.: US 2023/0389364 A1
(43) Pub. Date: Nov. 30, 2023

(54) DISPLAY PANEL AND METHOD OF MANUFACTURING THE SAME

(71) Applicant: Samsung Display Co., Ltd., Yongin-si (KR)

(72) Inventors: KEE-BUM PARK, Yongin-si (KR); GIHYEON SEONG, Yongin-si (KR)

(21) Appl. No.: 18/140,471

(22) Filed: Apr. 27, 2023

(30) Foreign Application Priority Data
May 31, 2022 (KR) 10-2022-0067183

(51) Int. Cl. H10K 59/122; H10K 59/12

(52) U.S. Cl. CPC H10K 59/122; H10K 59/1201

(57) ABSTRACT

A display panel includes a substrate, a plurality of pixel electrodes, a blocking electrode spaced apart from the plurality of pixel electrodes, a pixel definition layer in which first openings respectively exposing at least portions of the plurality of pixel electrodes and a second opening exposing at least a portion of the blocking electrode are defined, a plurality of light emitting layers in the first respective openings, a common electrode on the plurality of light emitting layers, an encapsulation layer on the common electrode, and a functional layer between the pixel definition layer and the common electrode, wherein an area except for the portion exposed by the second opening in the blocking electrode contacts the pixel definition layer, and the functional layer is connected in the first openings and is disconnected in the second opening.

### CROSS-REFERENCE TO RELATED APPLICATION

This application claims priority to and the benefit of Korean Patent Application No. 10-2022-0067183, filed on May 31, 2022, the entire contents of which are hereby incorporated herein by reference.

### BACKGROUND

### 1. Field

Aspects of an embodiment of the present disclosure relate to a display panel and a method of manufacturing the same.

### 2. Description of the Related Art

A self-emissive display device including a light emitting layer may include a plurality of light emitting regions divided by a plurality of light emitting elements. The light emitting regions may respectively include unique light emitting layers, and be independently driven through a pixel circuit. Here, the light emitting elements may include functional layers for enhancing light emission efficiency, and the functional layers may be provided as a single layer shared by the plurality of light emitting regions.

The above information disclosed in this Background section is only for enhancement of understanding of the background and therefore the information discussed in this Background section does not necessarily constitute prior art.

### SUMMARY

Aspects of an embodiment of the present disclosure include a display panel with relatively enhanced reliability and a simplified process.

A display device according to an embodiment of the inventive concept includes a support plate and a display panel.

According to an embodiment of the inventive concept include a display panel including: a substrate including a first area having light transmitted and a second area having a light transmissivity lower than the first area; a plurality of pixel electrodes in the second area; a blocking electrode on the substrate and spaced apart from the plurality of pixel electrodes; a pixel definition layer in which first openings respectively exposing at least portions of the plurality of pixel electrodes and a second opening exposing at least a portion of the blocking electrode are defined; a plurality of light emitting layers in the first respective openings; a common electrode on the plurality of light emitting layers; an encapsulation layer on the common electrode; and a functional layer between the pixel definition layer and the common electrode, wherein an area except for the portion exposed by the second opening in the blocking electrode contacts the pixel definition layer, and the functional layer is connected in the first openings and is disconnected in the second opening.

According to an embodiment, an inclination angle of a side surface defining the second opening in the pixel definition layer may be about 50 to about 90 degrees.

According to an embodiment, an inclination angle of a side surface defining the first openings in the pixel definition layer may be smaller than that of the side surface defining the second opening in the pixel definition layer.

According to an embodiment, the pixel definition layer may include an organic material.

According to an embodiment, the substrate may further include: a hole penetrating the first area; and a groove part defined between the hole and the pixel definition layer, and a portion of a top surface of which being removed, wherein the functional layer is disconnected in the groove part and the hole.

According to an embodiment, the substrate may include: a base layer including an organic material; a first intermediate barrier layer under the base layer and including an inorganic material; and a second intermediate barrier layer on the base layer and including an inorganic material, wherein the hole penetrates through the base layer, the first intermediate barrier layer, and the second intermediate barrier layer, and the groove part penetrates the base layer and the second intermediate barrier layer and exposes the first intermediate barrier layer.

According to an embodiment, the display panel may further include: additional pixel electrodes in the first area, wherein the first area includes a transmission region and a light emitting region, the additional pixel electrodes are spaced apart from the transmission region to be in the light emitting region, and an inclination angle of a side surface adjacent to the transmission region in the pixel definition layer is larger than that of the side surface defining the first opening.

According to an embodiment, the functional layer may be disconnected in the transmission region.

According to an embodiment, the second opening may include a plurality of sub-openings spaced apart from each other.

According to an embodiment, the blocking electrode may be provided in plurality and respectively overlapping the sub-openings.

According to an embodiment, the blocking electrode may overlap each of the sub-openings.

According to an embodiment, the display panel may further include a laminated structure in the second opening, wherein the laminated structure is separated from the functional layer and the common electrode.

According to an embodiment, the laminated structure may include the same material as any one of the functional layer and the common electrode.

According to an embodiment, the encapsulation may include at least one inorganic layer, and the disconnected portions of the functional layer are covered with the inorganic layer.

According to an embodiment of the inventive concept, a display panel manufacturing method includes: providing a substrate including a first sub-barrier layer including an inorganic material, a second sub-barrier layer on the first sub-barrier layer and including an inorganic material, and a base layer between the first sub-barrier layer and the second sub-barrier layer and including an organic material; providing a plurality of pixel electrodes and a blocking electrode on the substrate; providing a pixel definition layer in which a plurality of first openings respectively exposing the pixel electrodes are defined; providing a sacrificial layer on the substrate; providing a groove part on the substrate; providing a second opening exposing the blocking electrode in the pixel definition layer; removing the sacrificial layer; providing a functional layer on the pixel definition layer; providing a plurality of light emitting layers in the first openings; providing a common electrode on the plurality of light emitting layers; providing an encapsulation layer on the common electrode; and providing a hole in the substrate, wherein the second opening is provided after the plurality of first openings are provided, and the second opening is provided through a same process as the groove part.

According to an embodiment, a plurality of opening parts may be defined in the sacrificial layer, the groove part may be provided using a first opening part among the plurality of opening parts as a mask, and the second opening may be provided using a second opening part among the plurality of opening parts as a mask.

According to an embodiment, the providing the groove part may include: providing an opening in the second sub-barrier layer using the first opening part as the mask; and etching the base layer using the first opening part as the mask.

According to an embodiment, the providing the second opening may be substantially simultaneously performed with the etching the base layer.

According to an embodiment, the size of the second opening may be larger than that of the second opening part.

According to an embodiment, the sacrificial layer may include a transparent conductive oxide.

According to an embodiment, the functional layer may be provided through an evaporation process.

According to an embodiment, the functional layer may be disconnected in the groove part and the second opening to provide disconnected ends.

According to an embodiment, the providing the encapsulation layer may include depositing an inorganic material, and the inorganic material may commonly provided along the disconnected ends, the groove part, and the second opening.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1A and 1B are perspective views of an electronic device according to an embodiment of the inventive concept;

FIG. 2A is an exploded perspective view of an electronic device according to an embodiment of the inventive concept.

FIG. 2B is a block diagram of an electronic device according to an embodiment of the inventive concept;

FIG. 3A is a plan view of a display panel according to an embodiment of the inventive concept;

FIG. 3B is an expanded plan view of an area XX′ shown in FIG. 3A.

FIGS. 4A to 4C are cross-sectional views of a display panel according to an embodiment of the inventive concept;

FIG. 5A is a plan view according to an embodiment of the inventive concept.

FIG. 5B is a cross-sectional view of a partial area shown in FIG. 5A;

FIGS. 6A and 6B are cross-sectional views of portions of a display panel according to an embodiment of the inventive concept;

FIGS. 7A to 7D are plan views of partial areas of a display panel according to an embodiment of the inventive concept;

FIGS. 8A and 8B are plan views of some components of a display panel according to an embodiment of the inventive concept;

FIGS. 9A to 9P are cross-sectional views for explaining a manufacturing method of a display panel according to an embodiment of the inventive concept; and

FIGS. 10A and 10B are cross-sectional views of portions of a display panel according to an embodiment of the inventive concept.

### DETAILED DESCRIPTION

It will be understood that when an element (or area, layer, portion, or the like) is referred to as being “on”, “connected to” or “coupled to” another element, it can be directly on, connected or coupled to the other element or intervening third elements may be present.

Like reference numerals in the drawings refer to like elements. In addition, in the drawings, the thickness and the ratio and the dimension of the element are exaggerated for effective description of the technical contents.

The term “and/or” includes any and all combinations of one or more of the associated items.

Terms such as first, second, and the like may be used to describe various components, but these components should not be limited by the terms. These terms are only used to distinguish one element from another. For instance, a first component may be referred to as a second component, or similarly, a second component may be referred to as a first component, without departing from the scope of the present disclosure. The singular expressions include plural expressions unless the context clearly dictates otherwise.

In addition, the terms such as “under”, “lower”, “on”, and “upper” are used for explaining associations of items illustrated in the drawings. It will be understood that the spatially relative terms are intended to encompass different orientations of the device in use or operation in addition to the orientation depicted in the figures.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

It will be further understood that the terms “includes” and/or “including”, when used in this specification, specify the presence of stated features, integers, steps, operations, elements, components or combinations thereof, but do not preclude the presence or addition of one or more other features, integers, steps, operations, elements, components, or combinations thereof.

Hereinafter, aspects of an embodiment of the inventive concept will be described in more detail with reference to the accompanying drawings.

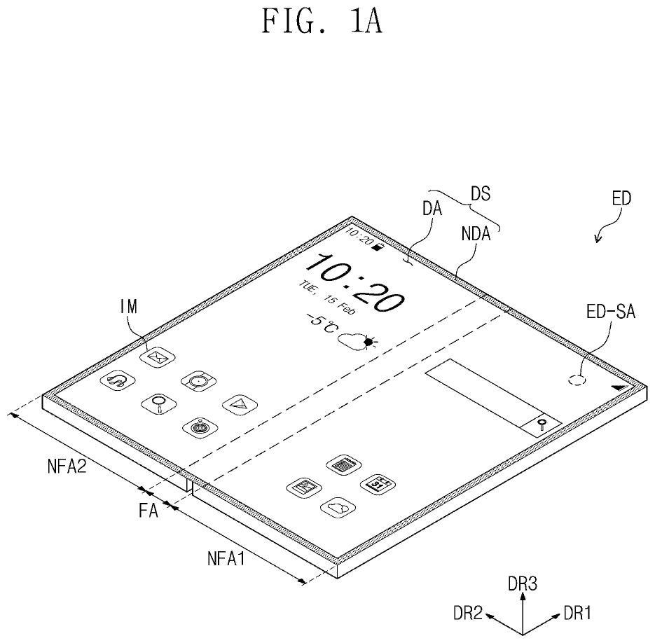

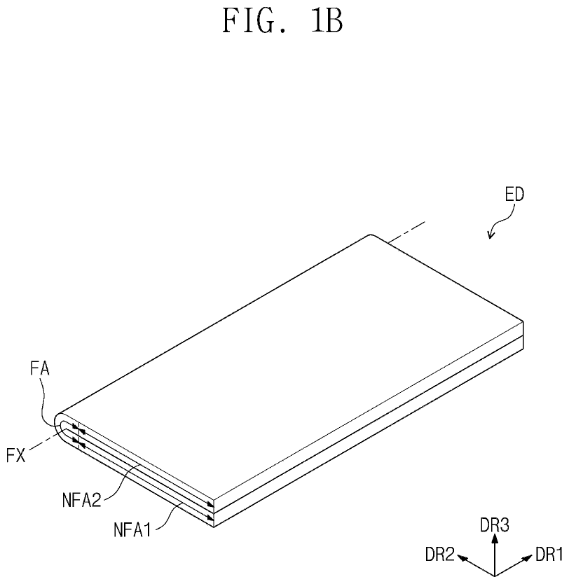

FIGS. 1A and 1B are perspective views of an electronic device according to an embodiment of the inventive concept. FIG. 1A illustrates a spread state (or an unfolded state) of the electronic device ED, and FIG. 1B illustrates a folded state of the electronic device ED.

Referring to FIGS. 1A and 1B, the electronic device ED according to an embodiment of the inventive concept may include a display surface DS defined by a first direction DR1 and a second direction DR2 that crosses the first direction DR1. The electronic device ED may provide a user with an image IM through the display surface DS.

The display surface DS may include a display area DA and a non-display area NDA around the display area DA. The display area DA may display the image IM, and the non-display area NDA may not display the image IM. The non-display area NDA may surround the display area DA. However, the embodiments of the inventive concept are not limited thereto, and the shapes of the display area DA and the non-display area NDA may be modified.

Hereinafter, a direction, which substantially vertically crosses the plane defined by the first and second directions DR1 and DR2, is defined as a third direction DR3. In addition, in the present specification, the expression “in a plan view” may mean a state of being viewed in the third direction DR3.

A sensing area ED-SA may be defined in the display area DA of the electronic ED. FIG. 1A illustrates an example of one sensing area ED-SA, but the number of the sensing areas ED-SA is not limited thereto. The sensing area ED-SA may be a portion of the display area DA. Accordingly, the electronic device ED may display an image through the sensing area ED-SA.

An electronic module may be located in an area overlapping the sensing area ED-SA. The electronic module may receive an external input delivered through the sensing area ED-SA or provide an output through the sensing area ED-SA. For example, the electronic module may be a sensor, such as a camera module or a proximity sensor configured to measure a distance, a sensor configured to recognize a body part (e.g., fingerprint, iris, or face) of the user, or a small lamp configured to output light, but is not particularly limited thereto. Hereinafter, an example that the electronic module overlapping the sensing area ED-DA is a camera module will be described.

The electronic module ED may include a folding area FA and a plurality of non-folding areas NFA1 and NFA2. The non-folding area NFA1 and NFA2 may include a first non-folding area NFA1 and a second non-folding area NFA2. In the second direction DR2, the folding area FA may be located between the first non-folding area NFA1 and the second non-folding area NFA2. The folding area FA is referred to as a foldable area, and the first and second non-folding areas NFA1 and NFA2 may be referred to as first and second non-foldable areas.

As shown in FIG. 1B, the folding area FA may be folded around a folding axis FX parallel to the first direction DR1. In a state where the electronic device ED is folded, the folding area FA has a prescribed curvature and radius of curvature. The first non-folding area NFA1 and the second non-folding area NFA2 may be opposite to each other, and the electronic device ED may be inner-folded so that the display surface DS is not exposed to the outside.

According to an embodiment of the inventive concept, the electronic device ED may be outer-folded so that the display surface DS is exposed to the outside. According to an embodiment of the inventive concept, the electronic device ED may be configured so that the inner-folding operation or the outer-folding operation are alternately repeated from an unfolding operation, but the embodiments of the inventive concept are not limited thereto. According to an embodiment of the inventive concept, the electronic device ED may be configured to select any one among the unfolding operation, the inner-folding operation, or the outer-folding operation.

In FIGS. 1A and 1B, the foldable electronic device ED is explained as an example, but the application of the inventive concept is not limited to the foldable electronic device ED. For example, the inventive concept may also be applied to a rigid electronic device, for example, an electronic device not including the folding area FA.

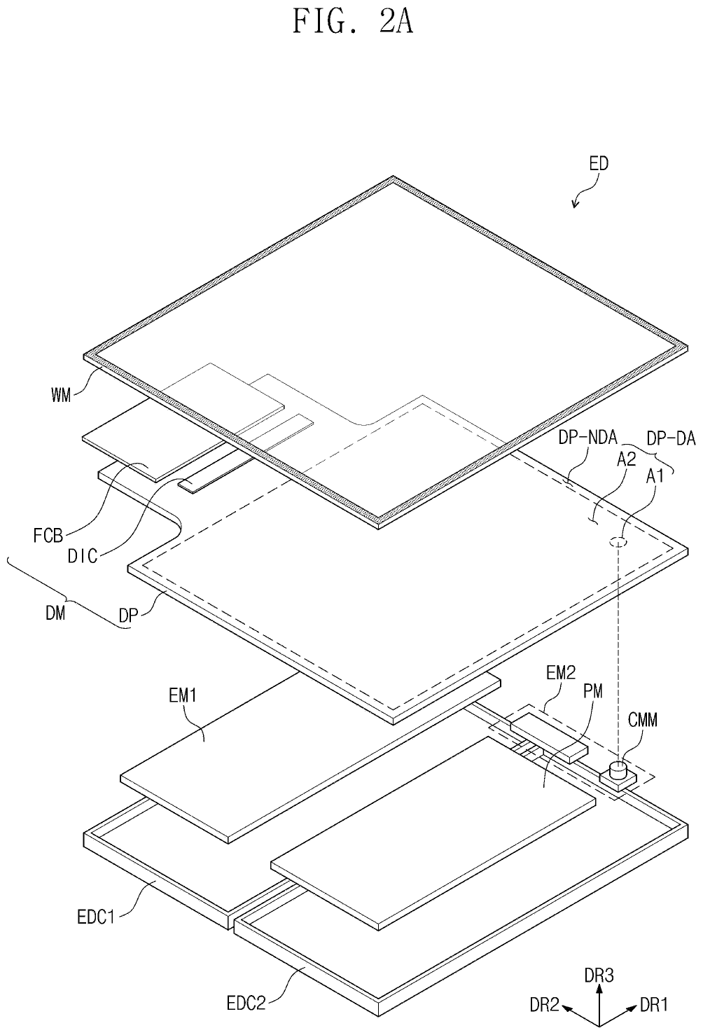

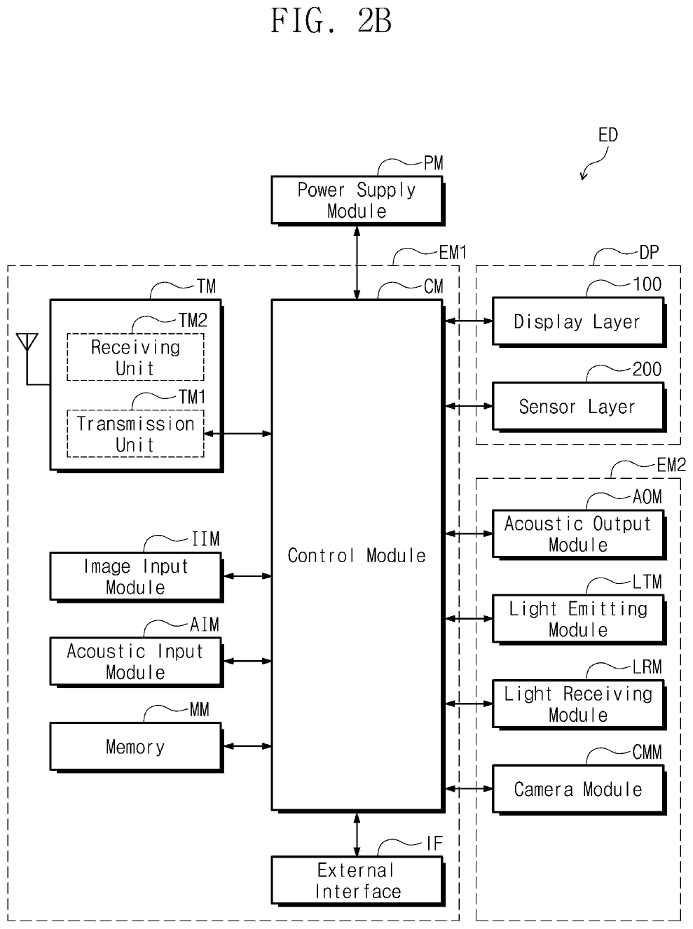

FIG. 2A is an exploded perspective view of an electronic device according to an embodiment of the inventive concept. FIG. 2B is a block diagram of an electronic device according to an embodiment of the inventive concept;

Referring to FIGS. 2A and 2B, the electronic device ED may include a display device DD, a first electronic module EM1, a second electronic module EM2, a power supply module PM, and housings EDC1 and EDC2. According to an embodiment, the electronic device ED may further include a mechanism structure for controlling a folding operation of the display device DD.

The display device DD includes a window module WM and a display module DM. The window module WM provides a front surface of the electronic device ED. The display module DM may include at least a display panel DP. The display module DM may generate an image and detect an external input.

In FIG. 2A, the display module DM is shown same as the display panel DP, but the display module DM may be substantially a laminated structure (or stacked structure) in which a plurality of components including the display panel DP are laminated. The laminated structure of the display module DM will be described in detail blow.

The display panel DP includes a display area DP-DA and a non-display area NDA DP-NDA) respectively corresponding to the display area DA (see FIG. 1A) and the non-display area NDA (see FIG. 1A). In the present specification, “an area/portion corresponds to an area/portion” means to overlap each other, and is not limited to having the same area.

The active area DP-DA may include a first area A1 and a second area A2. The first area A1 may overlap or correspond to the sensing area ED-SA (see FIG. 1A) of the electronic device ED. According to an embodiment, although shown in a circular shape, the first area A1 may have various shapes including a polygon, an ellipse, a figure having at least one curved side, or an atypical shape, and the first area A1 is not limited to any particular shape. The first area A1 may be referred to as a component area, and the second area A2 as a main display area or a general display area.

The first area A1 may have a higher light transmissivity than the second display area A2. In addition, the resolution of the first area A1 may be lower than that of the second area A2. The first area A1 may overlap the camera module CMM to be described below.

The display panel DP may include a display layer 100 and a sensor layer 200.

The display layer 100 may be a component configured to substantially generate an image. The display layer 100 may be an emissive display layer, for example, an organic light emitting display layer, an inorganic light emitting display layer, an organic-inorganic light emitting display layer, a quantum dot display layer, a micro LED display layer, or a nano LED display layer.

The sensor layer 200 may sense an external input applied from the outside. The external input may be a user input. The user input includes various types of external inputs including a body part (e.g., a finger) of the user, light, heat, a pen (e.g., a stylus), pressure or the like.

The display module DM may include a driving chip DIC located on the non-display area DP-NDA. The display module DM may further include a flexible circuit film FCB coupled to the non-display area DP-NDA.

The driving chip DIC may include driving elements, for example, a data driving circuit for driving pixels of the display panel DP. FIG. 2A illustrates a structure in which the driving chip DIC is mounted on the display panel DP, but the embodiments of the inventive concept are not limited thereto. For example, the driving chip DIC may be mounted on the flexible circuit board FCB.

The power supply module PM supplies power necessary for the entire operation of the electronic device ED. The power supply module PM may include a typical battery module.

The first electronic module EM1 and the second electronic module EM2 include various functional modules for operating the electronic device ED. Each of the first electronic module EM1 and the second electronic module EM2 may be directly mounted on a motherboard electrically connected with the display panel DP, or mounted on a separate substrate to be electrically connected to the motherboard through a connector, etc.

The first electronic module EM1 may include a control module CM, a wireless communication module TM, an image input module IIM, an acoustic input module AIM, a memory MM, and an external interface IF.

The control module CM controls the entire operation of the electronic device ED. The control module CM may be a microprocessor. For example, the control module CM may activate or deactivate the display panel DP. The control module CM may control other modules such as the image input module IIM or the acoustic input module AIM on the basis of a touch signal received from the display panel DP.

The wireless communication module TM may communicate with an external electronic device through a first network (e.g., a short-range communication network such as Bluetooth, WiFi direct, or infrared data association (IrDA)) or a second network (e.g., a long-range network such as cellular network, Internet, or computer network (e.g., LAN or WAN)). Communication modules included in the wireless communication module TM may be integrated into one component (e.g., a single chip), or be implemented with a plurality of separate components (e.g., a plurality of chips). The wireless communication module TM may transmit/receive a voice signal using a typical communication line. The wireless communication module TM may include a transmission unit TM1 that modulates a signal to be transmitted and transmits the modulated signal, and a receiving unit TM2 that demodulates a received signal.

The image input module IIM processes an image signal to convert the processed image signal into image data displayable on the display module DP. The acoustic input module AIM receives an external acoustic signal through a microphone in a recording mode or a voice recognition mode to convert the acoustic signal to electrical voice data.

The external interface IF may include a connector configured to physically connect the electronic device ED with the external electronic device. For example, the external interface IF may serve as an interface connected to an external charger, a wired/wireless data port, or a card socket (e.g., a memory card, a SIM/UIM card), etc.

The second electronic module EM2 may include an acoustic output module AOM, a light emitting module LTM, a light receiving module LRM and a camera module CMM, etc. The acoustic output module AOM performs conversion on acoustic data received from the wireless communication module TM or acoustic data stored in the memory MM, and outputs the converted result to the outside.

The light emitting module LTM generates and outputs light. The light emitting module LTM may output an infrared ray. The light emitting module LTM may include an LED element. The light receiving module LRM may sense the infrared ray. The light receiving module LRM may be activated when the infrared ray of a prescribed level or higher is sensed. The light receiving module LRM may include a CMOS sensor. After infrared light generated in the light emitting module LTM is output, the infrared light is reflected by an external object (e.g., a finger or the face of the user), and the reflected infrared light may be incident to the light receiving module LRM.

The camera module CMM may capture a static image or a moving image. The camera module CMM may be provided in plurality. Among them, some camera modules CMM may overlap the first area A1. An external input (e.g., light) may be provided to the camera module CMM through the first area A1. For example, the camera module CMM may receive natural light through the first area A1 to capture an external image.

The housings EDC1 and EDC2 may accommodate the display module DM, the first and second electronic modules EM1 and EM2, and the power supply module PM. The housings EDC1 and EDC2 may protect components such as the display module DM, the first and second electronic modules EM1 and EM2, and the power supply module PM that are accommodated therein. In FIG. 2A, the two housings EDC1 and EDC2 separated from each other are illustrated as an example, but are not limited thereto. According to an embodiment, the electronic device ED may further include a hinge structure for connecting the two housings EDC1 and EDC2. The housings EDC1 and EDC2 may be coupled with the window module WM.

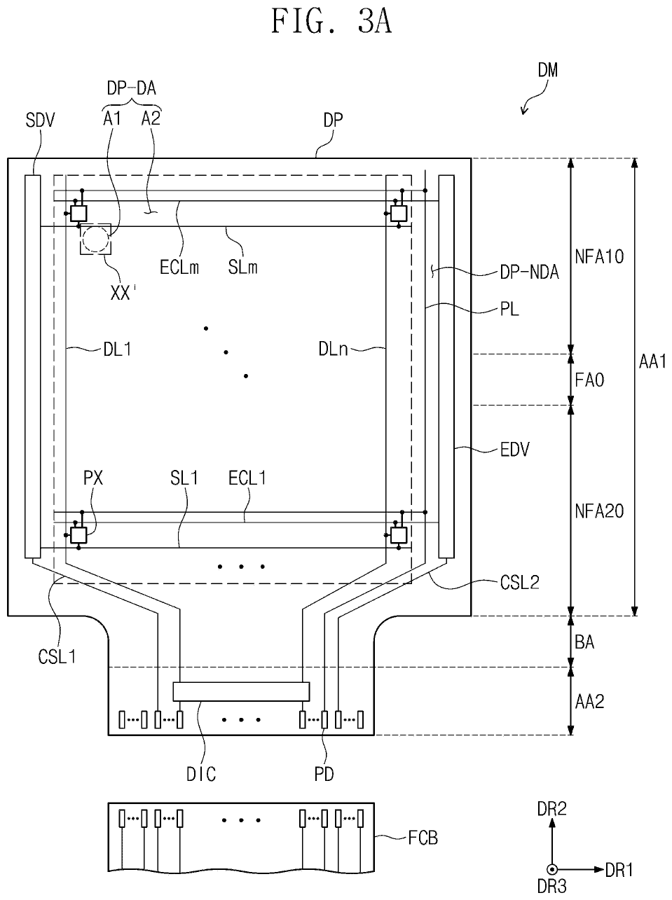

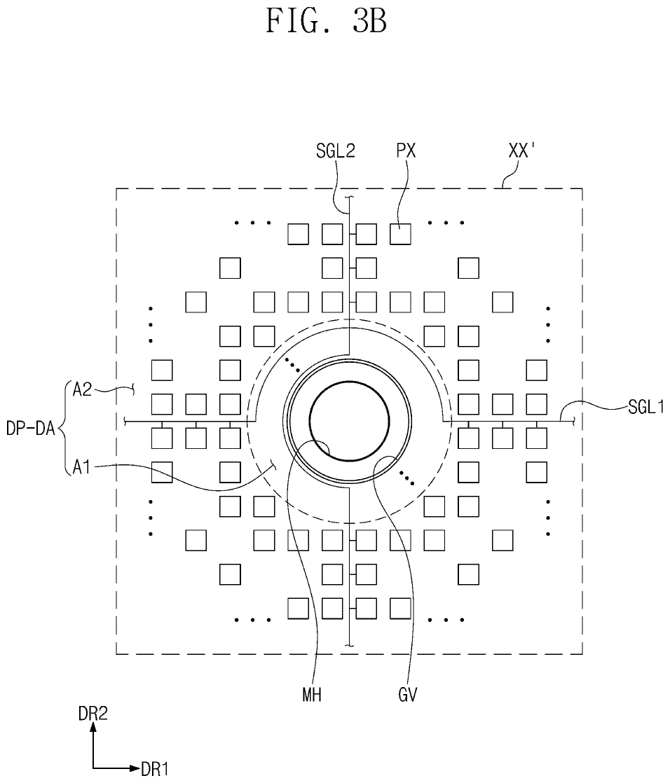

FIG. 3A is a plan view of a display panel according to an embodiment of the inventive concept. FIG. 3B is an expanded plan view of an area XX′ shown in FIG. 3A. In FIG. 3B, the pixels PX and some signal lines SL1 and SL2 are briefly shown for an easy description. Hereinafter, the inventive concept will be described with reference to FIGS. 3A to 3B.

Referring to FIG. 3A, a display area DP-DA and a non-display area DP-NDA around the display area DP-DA may be defined in the display panel DP. The display area DP-DA and the non-display area DP-NDA may be divided by the disposition of the plurality of pixels PX. The pixels PX are located in the display area DP-DA. A scan driving unit SDV, a data driving unit, and an emission driving unit EDV may be located in the non-display area DP-NDA. The data driving unit may be a partial circuit provided in the driving chip DIC.

The display area DP-DA may include a first area A1 and a second area A2. The first area A1 and the second area A2 may be divided by the spacing of pixels PX, the size of the pixels PX, or the presence or absence of the transmission region TP. According to an embodiment, the first area A1 may be an area in which the transmission region TP is located or a hole MH is provided.

The display panel DP may include a first panel area AA1 defined along the second direction DR2, a bending area BA, and a second panel area AA2. The second panel area AA2 and the bending area BA may be a partial area of the non-display area DP-NDA. The bending area BA is located between the first panel area AA1 and the second panel area AA2.

The first panel area AA1 corresponds to the display surface DS of FIG. 1A. The first panel area AA1 may include a first non-folding area NFA10, a second non-folding area NFA20, and a folding area FAO. The first non-folding area NFA10, the second non-folding area NFA20, and the folding area FAO may respectively correspond to the first non-folding area NFA1, the second non-folding area NFA2, and the folding area FA of FIGS. 1A and 1B.

The bending area BA may correspond to a bended area when the electronic device ED is assembled. The bending area BA is included in the display panel DP, and thus an electronic device having a narrow bezel may be easily implemented.

The width of the bending area BA parallel to the first direction DR1 and the width (or the length) of the second panel area AA2 may be smaller than the width (or the length) of the first panel area AA1 parallel to the first direction DR1. An area in which the length in a bending axis direction is shorter may be bent more easily.

The display panel DP may include the plurality of pixels PX, a plurality of scan lines SL1 to SLm, a plurality of data lines DL1 to DLn, a plurality of emission control lines ECL1 to ECLm, first and second control lines CSL1 and CSI2, a driving voltage line PL, and a plurality of pads PD. Here, m and n are natural numbers. The pixels PX may be connected to the scan lines SL1 to SLm, the data lines DL1 to DLn, and the emission control lines ECL1 ti ECLm.

The scan lines SL1 to SLm may extend in the first direction DR1 to be electrically connected to the scan driving unit SDV. The data lines DL1 to DLn may extend in the second direction DR2 to be electrically connected to the driving chip DIC via the bending area BA. The emission control lines ECL1 to ECLm may extend in the first direction DR1 to be electrically connected to the emission driving unit EDV.

The driving voltage line PL may include a portion extending in the first direction DR1 and a portion extending in the second direction DR2. The portion extending in the first direction DR1 and the portion extending in the second direction DR2 may be located on different layers. The portion extending in the second direction DR2 of the driving voltage line PL may extend to the second panel area AA2 via the bending area BA. The driving voltage line PL may provide a first voltage to the pixels PX.

The first control line CSL1 may be connected to the scan driving unit SDV, and extend towards the lower end of the second panel area AA2 via the bending area BA. The second control line CSL2 may be connected towards the emission driving unit EDV and extend to the lower end of the second panel area AA2 via the bending area BA.

In a plan view, the pads PD may be located adjacent to the lower end of the second panel area AA2. The driving chip DIC, the driving voltage line PL, the first control line CSL1, and the second control line CSL2 may be electrically connected to the pads PD. The flexible circuit board FCB may be electrically connected to the pads PD through an anisotropic conductive adhesive layer.

Referring to FIG. 3B, the pixels PX are arranged around the hole MH in the second area A2. The hole MH may be defined in the display area DP-DA. Accordingly, at least a portion of the pixels PX may be located adjacent to the hole MH. Some of the pixels PX may surround the hole MH.

A plurality of groove patterns GV1 and GV2 may be defined in the first area A1. The groove patterns GV1 and GV2 may be arranged along the edge of the hole MH in a plan view. The groove patterns GV1 and GV2 may include a first groove pattern GV1 located more adjacent to the second area A2 and a second groove pattern GV2 located more adjacent to the hole MH and smaller than the first groove pattern GV1. The first and second groove patterns GV1 and GV2 may be defined to be spaced apart from each other.

According to an embodiment, each of the first and second groove patterns GV1 and GV2 is shown in a shape of circular ring surrounding the hole MH. However, this is illustrated as an example, and the first and second groove patterns GV1 and GV2 may be provided to have the shape different from the hole MH, have the shape of a polygon, an ellipse, or a closed line shape including at least a partial curve, or have the shape including a plurality of partially disconnected patterns. In addition, the first and second groove patterns GV1 and GV2 may have different shapes, for example, the first groove pattern GV1 of a circle, the second groove part GV2 of a polygon, and are not limited to any one embodiment.

The groove patterns GV1 and GV2 may block a path in which moisture or oxygen permeable through the hole MH is flowed. A detailed description thereabout will be provided below.

The plurality of signal lines SGL1 and SGL2 connected to the pixels PX may be located in the first area A1. The signal lines SGL1 and SGL2 are connected to the pixels PX via a hole area HA. In FIG. 3B, two signal lines SGL1 and SGL2 among the plurality of signal lines connected to the pixels PX are shown as an example for easy description.

The first signal line SGL1 extends along the first direction DR1. The first signal line SGL1 is connected to the pixels arrayed in the same row along the first direction DR1 among the pixels PX. As an example, the first signal line SGL1 is described to correspond to any one among the scan lines SL1 to SLm.

Some of the pixels connected to the first signal line SGL1 are located in a left side around the hole MH, and the others are located in a right side around the hole MH. Accordingly, the pixels connected to the first signal line SGL1 in the same row may be turned on/off by the substantially same scan signal, even when some pixels around the hole MH are omitted.

The second signal line SGL2 extends along the second direction DR2. The second signal line SGL2 is connected to the pixels arranged in the same row along the second direction DR2 among the pixels PX. As an example, the second signal line SGL2 is described to correspond to any one among the data lines DL1 to DLn.

Some of the pixels connected to the second signal line SGL2 are located in an upper side around the hole MH, and the others are located in a lower side around the hole MH. Accordingly, the pixels connected to the second signal line SGL2 in the same row may receive a data signal through the same line, even when some pixels around the hole MH are omitted.

On the other hand, the display panel DP according to an embodiment of the inventive concept may further include a connection pattern located in the first area A1. Here, the first signal line SGL1 may be disconnected in an area overlapping the first area A1. The disconnected portions of the first signal line SGL1 may be connected through the connection pattern. Similarly, the second signal line SGL2 may be disconnected in the area overlapping the first area A1, and a connection pattern connecting the disconnected portions of the second signal line SGL2 may be further provided.

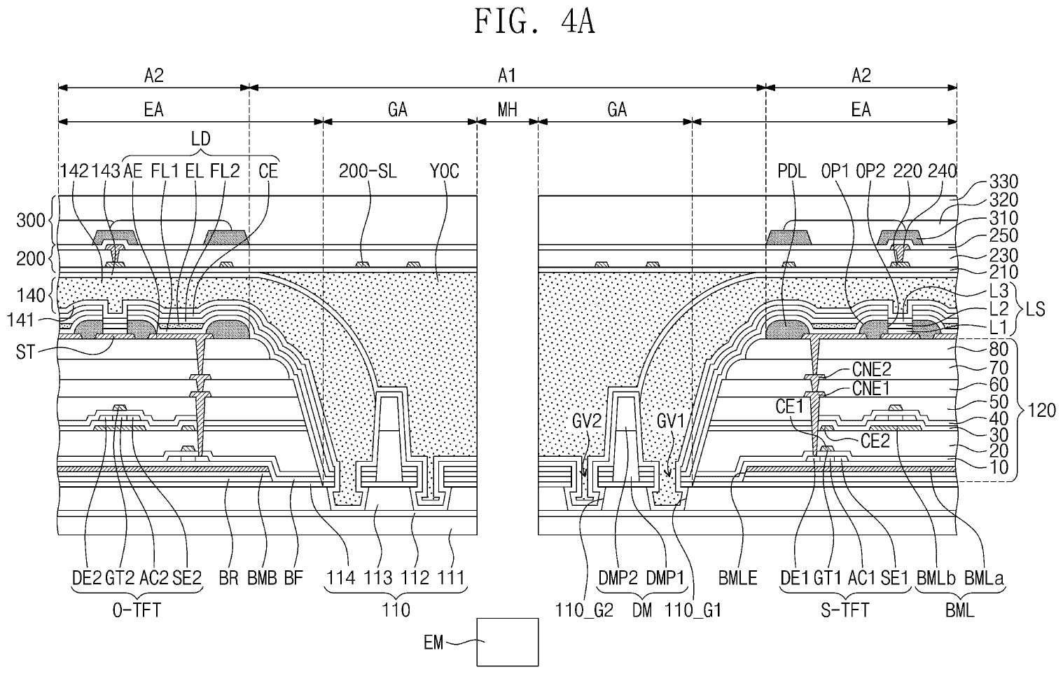

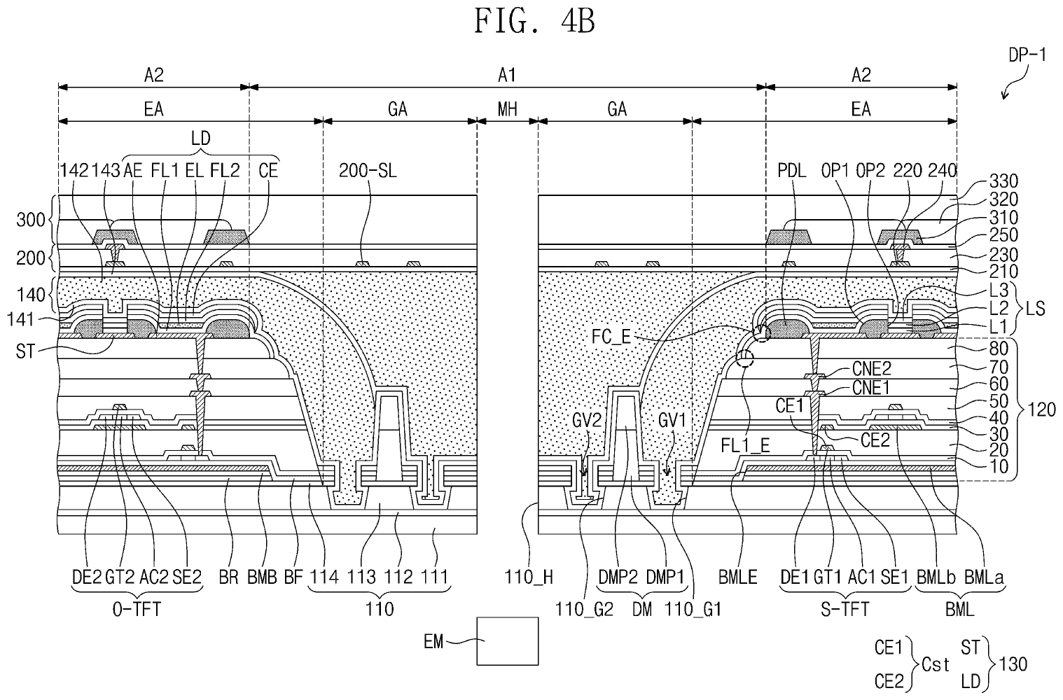

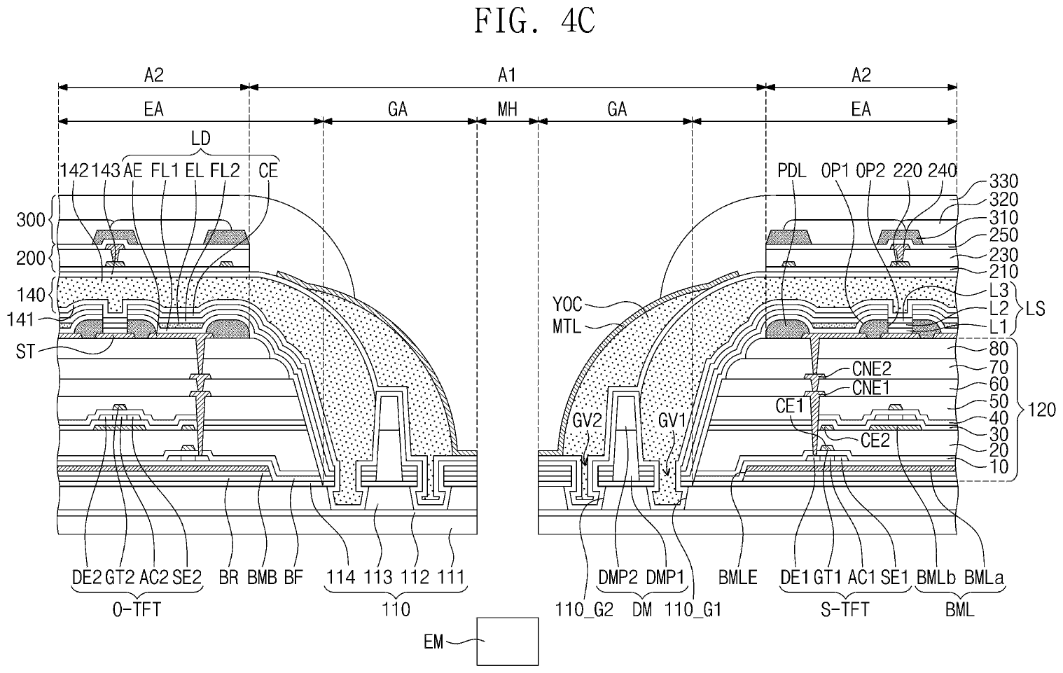

FIGS. 4A to 4C are cross-sectional views of a display panel according to an embodiment of the inventive concept. In FIGS. 4A to 4C, the first area A1 and the second area A2 adjacent thereto are partially illustrated. Hereinafter, the inventive concept will be described with reference to FIGS. 4A to 4C. Referring to FIG. 4A, the display panel DP may include a display layer 100, a sensor layer 200, and an anti-reflection layer 300. The display layer 100 may include a substrate 110, a circuit layer 120, a light emitting element layer 130, and an encapsulation layer 140. The substrate 110 may include a plurality of layers 111, 112, 113, and 114.

For example, the substrate 110 may include a sub-base layer 111, a first intermediate barrier layer 112, a second sub-base layer 113, and a second intermediate barrier layer 114. The first sub-base layer 111, the intermediate barrier layer 112, the second sub-base layer 113, and the second intermediate barrier layer 114 may be sequentially laminated in the third direction DR3.

Each of the first sub-base layer 111 and the second sub-base layer 113 may include at least one among a polyimide-based resin, an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, or a perylene-based resin. In addition, in the present specification, “-based resin” means to include “a functional group of”.

Each of the first and second intermediate barrier layers 112 and 114 may include at least one among silicon oxide, silicon nitride, silicon oxynitride, or amorphous silicon. For example, each of the first and second sub-base layers 111 and 113 may include polyimide, the first intermediate layer 112 may include silicon oxynitride SiON, and the second intermediate barrier layer 114 may include silicon oxide SiOX. In this case, the light transmissivity of the substrate 110 may be enhanced according to refractive index matching. However, this is illustrated as an example. The substrate 110 according to an embodiment of the inventive concept may be provided in a laminated structure of various material layers, or also in a single-layered structure, and is not limited to any one embodiment.

The barrier layer BR may be located on the substrate 110. The barrier layer BR may include an inorganic material. The barrier layer BR may include at least one among silicon oxide, silicon nitride, silicon oxynitride, or amorphous silicon. Alternatively, the barrier layer BR may be provided in a multi-layered structure. For example, the barrier layer BR may be provided with a structure in which a first layer including silicon oxynitride (SiON) and a second layer including silicon oxide (SiOX) are laminated. However, this is illustrated as an example. The barrier layer BR may be composed of various materials, and is not limited to any one embodiment. In addition, in the display panel DP according to an embodiment of the inventive concept, the barrier layer BR may be omitted.

A light shielding layer BML may be located on the barrier layer BR. The light shielding layer BML may include molybdenum (Mo), an alloy containing molybdenum, silver (Ag), an alloy containing silver, aluminum (Al), an alloy containing aluminum, aluminum nitride (AlN), Tungsten (W), Tungsten nitride (WN), Copper (Cu), Titanium (Ti), p+ doped amorphous silicon, MoTaOx and the like, but is not particularly limited thereto. The light shielding layer BML may be referred to as a rear metal layer or a rear layer.

At least one lower insulation layer BMB may be located between the light shielding layer BML and the barrier layer BR. A lower insulation layer opening ML-OP, which overlaps a first opening BM-OP, is defined in at least one lower insulation layer BMB. The first opening BM-OP and the lower insulation layer ML-OP may be substantially simultaneously provided through the same process. Accordingly, a side wall, defining the first opening BM-OP, of the light shielding layer BML may be arranged with a side wall, defining the lower insulation opening ML-OP, of the lower insulation layer BMB.

The lower insulation layer BMB may include an inorganic material. For example, the lower insulation layer BMB may include at least one among silicon oxide, silicon nitride, silicon oxynitride, or amorphous silicon. Alternatively, the lower insulation layer BMB may be provided in a multi-layered structure. For example, the lower insulation layer BMB may be provided with a structure in which a first layer including silicon oxide and a second layer including amorphous silicon are laminated.

When the lower insulation layer BMB has a multi-layered structure, destructive interference may occur in light passing through the lower insulation layer BMB according to refractive index matching between the layers. Accordingly, a probability that a noise image, for example, a ghost phenomenon occurs in an image acquired in the camera module CMM (see FIG. 2A) may be reduced or removed. Accordingly, the quality of a signal acquired or received from the camera module CMM (see FIG. 2A) may be enhanced. However, this is illustrated as an example, and the lower insulation layer BMB may be composed of various materials, and is not limited to any one embodiment. In addition, in the display panel DP according to an embodiment of the inventive concept, the lower insulation layer BMB may be omitted.

The buffer layer BF is located on the lower insulation layer BMB and the barrier layer BR, and may cover the light shielding layer BML. The buffer layer BF may prevent a phenomenon in which metal atoms or impurities diffuse to a first semiconductor pattern. In addition, the buffer layer BF may allow the first semiconductor pattern to be provided uniformly by adjusting a heat providing speed during a crystallization process.

The buffer layer BF may include at least one of silicon oxide, silicon nitride or silicon oxynitride. Alternatively, the barrier layer BF may have a multi-layered structure. For example, the buffer layer BF may have a structure in which a first layer including silicon nitride and a second layer including silicon oxide are laminated. However, this is explained as an example. The barrier layer BF may be composed of various materials, and is not limited to any one embodiment. In addition, in the display panel DP according to an embodiment of the inventive concept, the barrier layer BF may be omitted.

Each of the pixels may include a light emitting element LD, a silicon thin-film transistor S-TFT, an oxide thin-film transistor O-TFT, and a capacitor Cst. Meanwhile, each of the pixels may further include other thin-film transistors or capacitors other than the shown thin-film transistors or capacitor. In addition, the thin-film transistors configuring each of the pixels may include only silicon thin-film transistors S-TFT or only oxide thin-film transistors O-TFT. If the pixels could drive the light emitting element LD, the pixels according to an embodiment of the inventive concept may be designed in various structures, and are not limited to any one embodiment.

A first lower light shielding layer BMLa is located under the silicon thin-film transistor S-TFT, and a second lower light shielding layer BMLb is located under the oxide thin-film transistor O_TFT. In order to protect the pixel circuit, the first light shielding layer BMLa and the second light shielding layer BMLb may be respectively arranged to be overlapping the thin-film transistors S-TFT and O-TFT.

The first and second light shielding layers BMLa and BMLb may block an electronic potential from influencing the second pixel circuit PC2 due to a polarization phenomenon of the first sub-base layer 111 or the second sub-base layer 113. According to an embodiment of the inventive concept, the second light shielding layer BMLb may be omitted.

According to an embodiment, the first light shielding layer BMLa may be located on the lower insulation layer BMB. Meanwhile, the first light shielding layer BMLa may also be located in the barrier layer BR. For example, one portion of the barrier layer BR in the thickness direction is provided, and then the other portion of the barrier layer BR in the thickness direction is provided to cover the first light shielding layer BMLa. However, this is explained as an example. The light shielding layer BMLa may be located in various positions, and is not limited to any one embodiment.

The second light shielding layer BMLb may be located between the second insulation layer 20 and the third insulation layer 30. The second light shielding layer BMLb may be located on the same layer as a second electrode CE2 of the storage capacitor Cst. The second light shielding layer BMLb is connected with a contact electrode BL2-C to be applied with a static voltage or a signal. The contact electrode BL2-C may be located on the same layer as a gate GT2 of the oxide thin-film transistor O-TFT. The first and second light shielding layers BMLa and BMLb may include the same material, or different materials. However, this is illustrated as an example, and the contact electrode BL2-C may be located on the same layer as a first connection electrode CNE1 or a second connection electrode CNE2 to be described blow, and is not limited to any one embodiment.

The first semiconductor pattern may be located on the buffer layer BF. The first semiconductor pattern may include silicon semiconductor. For example, the silicon semiconductor may include amorphous silicon, polycrystalline, or the like. For example, the first semiconductor pattern may include low temperature polysilicon.

Meanwhile, in FIGS. 4A to 4C, only a portion of the first semiconductor pattern located on the buffer layer BF is shown, and the first semiconductor pattern may be further located in another area. The first semiconductor pattern may be arranged in a specific rule across the pixels. The first semiconductor pattern may have different electrical properties according to whether it is doped or not. The first semiconductor pattern may include a first area having high conductivity and a second area having low conductivity. The first area may be doped with an N-type dopant or a P-type dopant. A P-type transistor includes a doped area doped with a P-type dopant, and an N-type transistor includes a doped area doped with an N-type dopant. The second area may be a non-doped area, or be doped at a lower concentration relative to the first area.

The first area may have greater conductivity than the second area, and substantially operate as an electrode or a signal line. The second area may substantially correspond to an active area (or channel) of a transistor. In other words, a portion of the semiconductor pattern may be the active area of the transistor, another portion may be a source or a drain, and another portion may be a connection electrode or a signal connection line.

A source area SE1, an active area AC1, and a drain area DE1 of the silicon thin transistor S-TFT may be provided from the first semiconductor pattern. The source area SE1 and the drain area DE1 may extend in opposite directions from each other from the active area AC1 on a cross section.

The circuit layer 120 may include a plurality of inorganic insulation layers located on the light shielding layer BML. According to an embodiment, at least some of a first insulation layer 10 to a fifth insulation layer 50 sequentially laminated on the buffer layer BF may be inorganic insulation layers. For example, all the first to fifth insulation layers 10 to 50 may be inorganic insulation layers.

The first insulation layer 10 may be located on the buffer layer BF. The first insulation layer 10 may commonly overlap the plurality of pixels and cover the first semiconductor pattern. The first insulation layer 10 may include an inorganic layer and/or organic layer, and have a single layer or multilayer structure. The first insulation layer 10 may include at least one among aluminum oxides, titanium oxide, silicon oxide, silicon oxynitride, zirconium oxide, or hafnium oxide. According to an embodiment, the first insulation layer 10 may be a silicon oxide layer of a single layer. Not only the first insulation layer 10, but also an insulation layer of the circuit layer 120 to be described below may have a single layer or multilayer structure.

The gate GT1 of the silicon thin-film transistor S-TFT may be located on the first insulation layer 10. The gate GT1 may be a portion of a metal pattern. The gate GT1 may overlap the active area AC1. In a process of doping the first semiconductor pattern, the gate GT1 may function as a mask. The gate GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), or the like, but is not particularly limited thereto.

The second insulation layer 20 may be located on the first insulation layer 10 and cover the gate GT1. The second insulation layer 20 may be an inorganic layer, and have a single layer or multilayer structure. The second insulation layer 20 may include at least one among aluminum oxide, titanium oxide, silicon oxide, or silicon oxynitride. According to an embodiment, the second insulation layer 20 may have a multilayer structure including a silicon oxide layer and a silicon nitride layer.

The third insulation layer 30 may be located on the second insulation layer 20. The third insulation layer 30 may be an inorganic layer, and have a single layer or multilayer structure. For example, the third insulation layer 30 may have a multilayer structure including silicon oxide layer and silicon nitride layer. A second capacitor electrode CE2 of the storage capacitor Cst may be located between the second insulation layer 20 and the third insulation layer 30. In addition, a first capacitor electrode CE1 of the storage capacitor Cst may be located between the first insulation layer 10 and the second insulation layer 20.

A second semiconductor pattern may be located on the third insulation layer 30. The second semiconductor pattern may include a silicon oxide semiconductor. The silicon oxide semiconductor may include a plurality of areas divided according to whether a metal oxide is reduced. An area (hereinafter, reduction area) in which the metal oxide is reduced has high conductivity in comparison to an area (hereinafter, non-reduction area) in which the metal oxide is not reduced. The reduction zone may substantially serve as a source/drain or a signal line of the transistor. The non-reduction area substantially corresponds to the active area (or semiconductor area, channel) of the transistor. In other words, a portion of the second semiconductor pattern may be the active area of the transistor, another portion may be a source/drain area of the transistor, and another portion may be a signal transfer area.

A source area SE2, an active area AC2, and a drain area DE2 of the oxide silicon thin-film transistor O-TFT may be provided from the second semiconductor pattern. The source area SE2 and the drain area DE2 may extend in opposite directions from each other from the active area AC2 on a cross section.

The fourth insulation layer 40 may be located on the third insulation layer 30. The fourth insulation layer 40 may commonly overlap the plurality of pixels and cover the second semiconductor pattern. The fourth insulation layer 40 may be an inorganic layer, and have a single layer or multilayer structure. The fourth insulation layer 40 may include at least one among aluminum oxide, titanium oxide, silicon oxide, silicon nitride, silicon oxynitride, zirconium oxide, or hafnium oxide.

The gate GT2 of the oxide thin-film transistor O-TFT may be located on the fourth insulation layer 40. The gate GT2 may be a portion of a metal pattern. The gate GT2 may overlap the active area AC2. In a process of doping the second semiconductor pattern, the gate GT2 may function as a mask.

The fifth insulation layer 50 may be located on the fourth insulation layer 40 and cover the gate GT2. The fifth insulation layer 50 may be an inorganic and/or organic layer, and have a single layer or multilayer structure.

The first connection electrode CNE1 may be located on the fifth insulation layer 50. The first connection electrode CNE1 may be connected to the drain area DE1 of the silicon thin-film transistor S-TFT through a contact hole penetrating through the first to fifth insulation layers 10 to 50. Meanwhile, according to an embodiment, the display panel DP may further include a connection electrode that is defined at a position corresponding to the first connection electrode CNE1 and is connected to the drain area DE2 or the source area SE2 of the oxide thin-film transistor O-TFT, and is not limited to any one embodiment.

The circuit layer 120 may include a plurality of organic insulation layers located on the plurality of inorganic insulation layers. For example, at least one of the sixth to eighth insulation layers 60, 70, or 80 may be an organic insulation layer.

The sixth insulation layer 60 may be located on the fifth insulation layer 50. The sixth insulation layer 60 may include an organic material, for example, a polyimide-based resin. The second connection electrode CNE2 may be located on the sixth insulation layer 60. The second connection electrode CNE2 may be connected to the first connection electrode CNE1 through a contact hole CNT3 penetrating through the sixth insulation layer 60.

The seventh insulation layer 70 may be located on the sixth insulation layer 60 to cover the second connection electrode CNE2. The eighth insulation layer 80 may be located on the seventh insulation layer 70.

Each of the sixth to eighth insulation layers 60 to 80 may be an organic layer. In the present specification, the sixth insulation layer 60 may be referred to as a first organic insulation layer, the seventh insulation layer 70 as a second organic layer, and the eighth insulation layer 80 as a third organic layer. For example, each of the sixth to eighth insulation layers 60 to 80 may include a general purpose polymer such as Benzocyclobutene (BCB), polyimide, Hexamethyldisiloxane (HMDSO), Polymethylmethacrylate (PMMA), or Polystyrene (PS), a polymer derivative having a phenol-based group, an acryl-based polymer, an imide-based polymer, an allyl ether-based polymer, an amide-based polymer, a fluorine-based polymer, a p-xylene-based polymer, a vinylalcohol-based polymer, or a blend thereof.

The light emitting element layer 130 including a light emitting element LD may be located on the circuit layer 120. The light emitting element LD may include a first electrode AE, a first functional layer HFL, a light emitting layer EL, a second functional layer EFL, and a second electrode CE. Each of the first functional layer HFL, the second functional layer EFL, and the second electrode CE may be an integrated layer commonly provided for each of the pixels PX (see FIG. 2).

The first electrode AE may be located on the eighth insulation layer 80. The first electrode AE may be a (semi-) transparent electrode or a reflective electrode. According to an embodiment, the first electrode AE may include a reflection layer composed of Ag, Mg, Al, Pt, Pd, Au, Ni, Nd, Ir, Cr, or a compound thereof, and a transparent or semi-transparent electrode layer provided on the reflection layer. The transparent or semi-transparent electrode layer may include at least one or more selected from the group consisting of indium tin oxide (ITO), indium zinc oxide (IZO), indium gallium zinc oxide (IGZO), zinc oxide (ZnO) or indium oxide (In2O3), aluminum doped zinc oxide (AZO), and a combination thereof. For example, the first electrode AE may be provided with ITO/Ag/ITO.

Meanwhile, according to an embodiment, the first electrode AE is shown connected to the silicon thin-film transistor S-TFT via the first connection electrode CNE1 and the second connection electrode CNE2. However, this is an example, and the electrode AE may be connected to the oxide thin-film transistor O-TFT, and is not limited to any one embodiment.

A pixel definition layer PDL may be located on the eighth insulation layer 80. The pixel definition layer PDL may have light absorption property, and have a block color. The pixel definition layer PDL may include a black coloring agent. The black coloring agent may include a black dye or a black pigment. The black coloring agent may include carbon black, a metal such as chromium, or an oxide thereof.

In the pixel definition layer PDL, a first opening OP1 may be defined to expose a portion of the first electrode AE. In other words, the pixel definition layer PDL may cover the edge of the first electrode AE. In addition, the pixel definition layer PDL may cover a side surface, adjacent to the transmission region TP, of the eighth insulation layer 80.

The first functional layer HFL may be located on the first electrode AE and the pixel definition layer PDL. The first functional layer HFL may include a hole transport layer (HTL), a hole injection layer (HIL), or all the HTL and HIL. The first functional layer HFL may be arranged in the entirety of the first area A1 and the second area A2, and also in the transmission region TP.

The light emitting layer EL may be located on the first functional layer HFL, and in an area corresponding to the first opening OP1 of the pixel definition layer PDL. The light emitting layer EL may include an organic material, an inorganic material, or an organic-inorganic material that emits light of a prescribed color. The light emitting layer EL may be located in the first area A1 and the second area A2. The light emitting layer EL located in the first area A1 may be located in an area spaced apart from the transmission region TP, namely, an element area EP.

The second functional layer EFL may be located on the first functional layer HFL, and cover the light emitting layer EL. The second functional layer EFL may include an electron transport layer (ETL), an electron injection layer (EIL), or all the ETL and EIL. The second functional layer EFL may be located in the entirety of the first area A1 and the second area A2, and also in the transmission region TP.

The second electrode CE may be located on the second functional layer EFL. The second electrode CE may be located in the first area A1 and the second area A2. An electrode opening CE-OP, which overlaps the first opening BM-OP, is defined in the second electrode CE. A minimum width of the electrode opening CE-OP may be larger than that of the first opening BM-OP of the light shielding layer BML.

According to an embodiment, the light emitting element layer 130 may further include a capping layer located on the second electrode CE. The capping layer may include LiF, an inorganic material, or/and, an organic material.

In addition, according to an embodiment, the light emitting element layer 130 may further include a spacer. The spacer may be located on the pixel definition layer PDL. The spacer may be a component configured to support components included in the circuit layer 120 and the light emitting element layer 130 that are located in a lower part to be spaced apart from components included in the sensor layer 200 and the anti-reflection layer 300 that are located in an upper part. The spacer may include an inorganic material. The spacer may also include a black component as the pixel definition layer PDL.

The encapsulation layer 140 may be located on the light emitting element layer 130. The encapsulation layer 140 may include a first inorganic layer 141, an organic layer 142 and a second inorganic layer 143 that are sequentially laminated. However, the embodiments of the inventive concept are not limited thereto, and the encapsulation layer 140 may further include a plurality of inorganic layers and organic layers.

The first and second inorganic layers 141 and 143 protect the light emitting element layer 130 from moisture and oxygen, and the organic layer 142 may protect the light emitting element layer 130 from a foreign matter such as a dust particle. The first and second inorganic layers 141 and 143 may include a silicon nitride layer, a silicon oxynitride layer, a silicon oxide layer, a titanium oxide layer, an aluminum oxide layer or the like. The organic layer 142 may include an acrylic-based organic layer, but is not limited thereto.

The sensor layer 200 may be located on the display layer 100. The sensor layer 200 may be referred to as a sensor, an input sensing layer, or an input sensing panel. The sensing layer 200 may include a sensor base layer 210, a first sensor conductive layer 220, a sensor insulation layer 230, a second sensor conductive layer 240, and a sensor cover layer 250.

The sensor base layer 210 may be directly located on the display layer 100. The sensor base layer 210 may be an inorganic layer including any one among silicon nitride, silicon oxynitride, or silicon oxide. Alternatively, the sensor base layer 210 may be an organic layer including an epoxy resin, an acrylic resin, or an imide-based resin. The sensor base layer 210 may have a single layer structure, or a multilayer structure laminated along the third direction DR3.

Each of the first sensor conductive layer 220 and the second sensor conductive layer 240 may have a single layer structure or a multilayer structure laminated along the third direction DR3.

The conductive layer of the single layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), indium zinc tin oxide (IZTO), or the like. Besides, the transparent conductive layer may include a conductive polymer such as PEDOT, a metal nano-wire, graphene or the like.

The conductive layer of the multilayer structure may include metal layers. For example, the layers may have a three-layer structure of titanium/aluminum/titanium. The conductive layer of the multilayer structure may include at least one metal layer and at least one transparent conductive layer.

The sensor insulation layer 230 may be located between the first sensor conductive layer 220 and the second sensor conductive layer 240. The sensor insulation layer 230 may include an inorganic film. The inorganic film may include at least one among aluminum oxide, titanium oxide, silicon oxide, silicon nitride, silicon oxynitride, zirconium oxide, or hafnium oxide.

The sensor insulation layer 230 may include an organic film. The organic film may include at least one among an acrylic-based resin, a meta-acrylic-based resin, polyisoprene, a vinyl-based resin, an epoxy-based resin, an urethane-based resin, a cellulose-based resin, a siloxane-based resin, a polyimide based-resin, a polyamide-resin, or a parylene-based resin.

The sensor cover layer 250 may be located on the sensor insulation layer 230 and cover the second sensor conductive layer 240. The second sensor conductive layer 240 may include a conductive pattern 240P (see FIG. 4). The sensor cover layer 250 may cover the conductive pattern 240P, and reduce or remove a probability that the conductive pattern 240P is damaged in subsequent processes.

The sensor cover layer 250 may include an inorganic material. For example, the sensor cover layer 250 may include silicon nitride, but is not particularly limited thereto.

The anti-reflection layer 300 may be located on the sensor layer 200. The anti-reflection layer 300 may include a division layer 310, a plurality of color filters 320, and a planarization layer 330. The division layer 310 and the color filters 320 are not located in the transmission region TP of the first area A1.

The division layer 310 may be arranged to be overlapping the second sensor conductive layer 240. The conductive pattern 240P according to an embodiment may correspond to the second sensor conductive layer 240. The sensor cover layer 250 may be located between the division layer 310 and the second sensor conductive layer 240. The division layer 310 may prevent reflection of external light by the second sensor conductive layer 240. A material defining the division layer 310 may be used without limitation if the material absorbs light. The division layer 310 is a layer having black color, and, according to an embodiment, may include a black coloring agent. The black coloring agent may include a black dye or a black pigment. The black coloring agent may include carbon black, a metal such as chromium, or an oxide thereof.

A plurality of division openings 310-OP may be defined in the division layer 310. The plurality of division openings 310-OP may respectively overlap the plurality of light emitting layers EL. The color filters 320 may be arranged in correspondence to the plurality of division openings 310-OP. The color filters 320 may transmit light provided from the light emitting layer EL overlapping the color filters 320.

The planarization layer 330 may cover the division layer 310 and the color filters 320. The planarization layer 330 may include an organic material, and provide a planar surface on the top surface of the planarization layer 330. According to an embodiment of the inventive concept, the planarization layer 330 may be omitted.

As described above, the hole MH, the first and second groove patterns GV1 and GV2 may be defined in the first area A1. The hole MH may be defined to penetrate through the substrate 110. According to an embodiment, the hole MH may penetrate through the layers 111, 112, 113, and 114 constituting the substrate 110, and the inorganic layers 141 and 143 constituting the encapsulation layer 140, and entirely penetrate the display panel DP in the thickness direction DR3.

The first and second groove patterns GV1 and GV2 may be defined in the substrate 110. Specifically, the first groove pattern GV1 may be defined closer to the second area A2 than the second groove pattern GV2 is. The first groove pattern GV1 may be provided by the first inorganic layer 141 covering a groove part 110_G1 that is defined by removing some layers in the substrate 110. The first groove pattern GV1 may be filled with the inorganic layer 142 of the encapsulation layer 140.

The second groove pattern GV2 may be defined closer to the hole MH than the first groove pattern GV2 is. The second groove pattern GV2 may be provided by the first and second inorganic layer 141 and 143 covering a groove part 110_G2 that is defined by removing some layers in the substrate 110. The second groove pattern GV2 may be exposed from the organic layer 142 of the encapsulation layer 140.

The second groove pattern GV2 may be filled with the planarization layer YOC. The planarization layer YOC is located in the first area A1 to cover ridges provided by the groove pattern GV2 or a dam part DM. The sensor layer 200 and the anti-reflection layer 300 may be located on the planarization layer YOC. The planarization layer YOC may provide the planar surface on the top surface. Accordingly, some wirings 200_SL in the sensor layer 200 may also be located in the first area A1. Accordingly, interference between signal lines may be prevented in the sensor layer 200 to reduce a noise or the like.

The dam part DM is located between the first groove pattern GV1 and the second groove pattern GV2. The dam part DM is shown as a structure in which two layers DMP1 and DMP2 are laminated, but is illustrated as an example. The dam part DM may have a single layer structure, and a structure in which much more number of layers are laminated. In addition, the dam part DM may be provided in plurality. The dam part DM may prevent overflow of the organic layer 142.

Meanwhile, according to an embodiment, organic patterns may be located in the groove parts 110_G1 and 110_G2. The organic pattern may be separated from the first functional layer FL1 or the second functional layer FL2. According to an embodiment of the inventive concept, each of the first functional layer FL1 and the second functional layer FL2 may be provided in the first area A1 with a plurality of patterns separated by the groove patterns GV1 and GV2.

Specifically, in each of the first functional layer FL1 and the second functional layer FL2, a portion located between the hole MH and the second groove pattern GV2 may be discontinuous with a portion located between the first groove pattern GV1 and the second groove pattern GV2. In addition, in each of the first functional layer FL1 and the second functional layer FL2, the portion located between the first groove pattern GV1 and the second groove pattern GV2 may be discontinuous with a portion located in the second area A2. In other words, the display panel DP blocks the continuity of the first and second functional layers FL1 and FL2 in the first area A1 and the second area A2 through the groove patterns GV1 and GV2. Accordingly, even when permeated through the first and second functional layers FL1 and FL2 exposed by the hole MH, external moisture, contamination or the like is prevented from reaching the second area A2. Accordingly, the reliability of the display panel DP may be improved.

Meanwhile, according to an embodiment, the light emitting element layer 130 may further include a blocking electrode ST. The blocking electrode ST may be located on the eighth insulation layer 80. The blocking electrode ST may be located on the same layer as the first electrode AE. The first electrode AE and the blocking electrode ST may be substantially simultaneously patterned through one mask from a single conductive layer. Accordingly, because an additional process of providing the blocking electrode DT is not necessary, the entire process may be simplified.

In the pixel definition layer PDL, a second opening OP2 exposing at least a portion of the blocking electrode ST may be defined. The second opening OP2 may overlap the blocking electrode ST in a plane view and have a smaller planar area than the blocking electrode ST.

The pixel definition layer PDL covers the edge of the blocking electrode ST. An area, overlapping the pixel definition layer PDL in a plan view, of the blocking electrode ST may contact the pixel definition layer PDL. In other words, an area that is not exposed by the second opening OP2 in the top surface of the blocking electrode ST may be entirely covered with the pixel definition layer PDL.

A prescribed laminated structure LS may be located in the second opening OP2. The laminated structure LS may include first to third layers L1, L2, and L3. The first layer L1 may include the substantially same material as the first insulation layer FL1. The first layer L1 may be provided together with the first functional layer FL1. The first layer L1 and the first functional layer FL1 provide a step and are disconnected from each other.

The second layer L2 is located on the first layer L1. The second layer L2 may include the substantially same material as the second functional layer FL2. The second layer L2 may be provided together with the second functional layer FL2. The second layer L2 and the second functional layer FL2 provide a step and are disconnected from each other.

The third layer L3 is located on the second layer L2. The third layer L3 may include the substantially same material as the second electrode CE. The third layer L3 may be provided together with the second electrode CE. The third layer L3 and the second electrode CE provide a step and are disconnected from each other.

According to an embodiment of the inventive concept, each of the first functional layer FL1 and the second functional layer FL2 may be provided in the second area A2 with a plurality of separate patterns separated by the second opening OP2. Specifically, in each of the first functional layer FL1 and the second functional layer FL2, portions, which define light emitting elements adjacent to each other with the second opening OP2 interposed therebetween, may be discontinuous with each other. In other words, the display panel DP blocks the continuity of the first and second functional layers FL1 and FL2 in the second area A2 through the second opening OP2. The display panel DP may separate the first functional layer FL1 from the second functional layer FL2 for each pixel.

According to an embodiment of the inventive concept, the first and second functional layers FL1 and FL2 are separated from each other for each adjacent pixel, and thus a side current leakage phenomenon may be prevented. Specifically, as one functional layer is commonly provided between a plurality of light emitting regions, a current leakage phenomenon may occur between adjacent pixels. Accordingly, light may be emitted from the adjacent pixels, color mixing between the pixels may occur, and thus it becomes difficult to drive the pixels independently. According to an embodiment of the inventive concept, the first and second functional layers FL1 and FL2 commonly provided to the plurality of pixels may be separated from an adjacent area through the second opening OP2 provided in the pixel definition layer PDL. Accordingly, when a current for driving a specific pixel is applied, a current leakage issue that the current flows to another adjacent pixel may be prevented by the first and second functional layers FL1 and FL2. Therefore, a color mixing defect for each pixel may be prevented. In addition, according to an embodiment of the inventive concept, brightness degradation or an increase in consumption power may also be prevented.

The second opening OP2 may be provided in various shapes. For example, the second opening OP2 may be provided according to pixel definition layers. In this case, the second opening OP2 in a plan view may have a single lattice shape. Alternatively, the second opening OP2 may be provided only between the adjacent light emitting regions. In this case, the second opening OP2 may be separately provided in plurality. Alternatively, the second opening OP2 may also be divided into a plurality of openings between two light emitting regions. The second opening OP2 according to an embodiment of the inventive concept may be provided in various shapes, and is not limited to any one embodiment.

The blocking electrode ST may have a larger shape in at least a plan view than the second opening OP2. Accordingly, the blocking electrode ST includes at least a portion covered by the pixel definition layer PDL and at least a portion exposed by the second opening OP2. The blocking electrode ST may have the shape corresponding to that of the second opening OP2. For example, the block electrode ST may be provided in a lattice shape or with a plurality of patterns. Each of the plurality of patterns may be similar to the first electrode AE, but be provided in an area smaller than that of the first electrode AE. Alternatively, each of the plurality of patterns may have a different shape different from the first electrode AE. If located between the pixel electrodes AE and overlaps the second opening OP2, each of the plurality of patterns may have various shapes such as a circle, an ellipse, a polygon, or an atypical shape, and is not limited to any one embodiment.

Referring to FIG. 4B, in a display panel DP-1, the first and second functional layers FL1 and FL2 may be partially disconnected by the pixel definition layer PDL in an area adjacent to the first area A1. The ends of the first and second functional layers FL1 and FL2 located in the second area A2 may be present on the side surface of the pixel definition layer PDL. In other words, the first and second functional layers FL1 and FL2 may be disconnected between the first area A1 and the second area A2 by controlling an inclination angle of a side surface, facing the first area A1, of the pixel definition layer PDL. Accordingly, an end FL1_E of the first functional layer FL1 may be provided on the side surface of the eighth insulation layer 80, and ends FC_E of the second functional layer FL2 and the second electrode CE may be provided on the side surface of the pixel definition layer PDL. According to an embodiment of the inventive concept, even when a separate mask is not added, the continuity between the first area A1 and the second area A2 may be blocked with respect to each of the first and second functional layers FL1 and FL2.

Referring to FIG. 4C, in the display panel DP-2, the planarization layer YOC may not be exposed by the hole MH. According to an embodiment, the planarization layer YOC fills the second groove pattern GV2 and exposes a portion adjacent to the hole MH. The portion adjacent to the hole MH in the planarization layer YOC may be covered by a metal cover layer MTL. According to an embodiment of the inventive concept, because the planarization layer YOC is not exposed by the hole MH, lifting of the planarization layer YOC or permeation of moisture or contamination into the planarization layer YOC may be prevented to improve the reliability of the display panel DP-2.

The display panels DP, DP-1 and DP-2 according to an embodiment of the inventive concept may have various structures including a structure in which the organic layers FL1 and FL2 are disconnected in the second area A2 through the second opening OP2, and are not limited to any one embodiment.

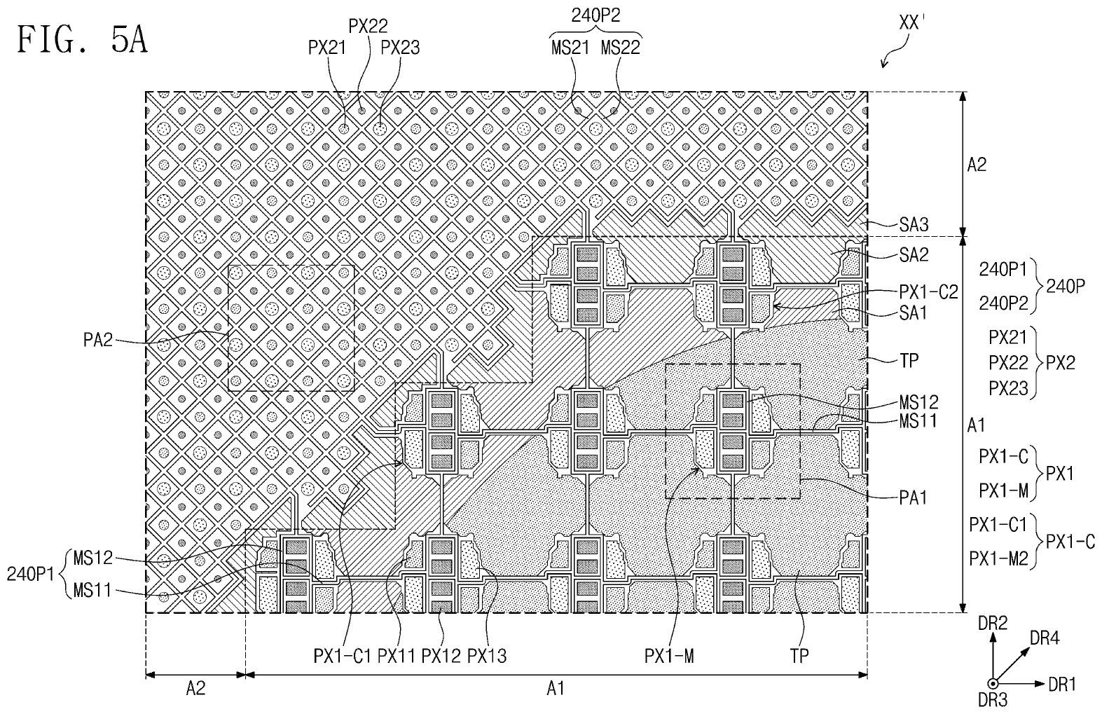

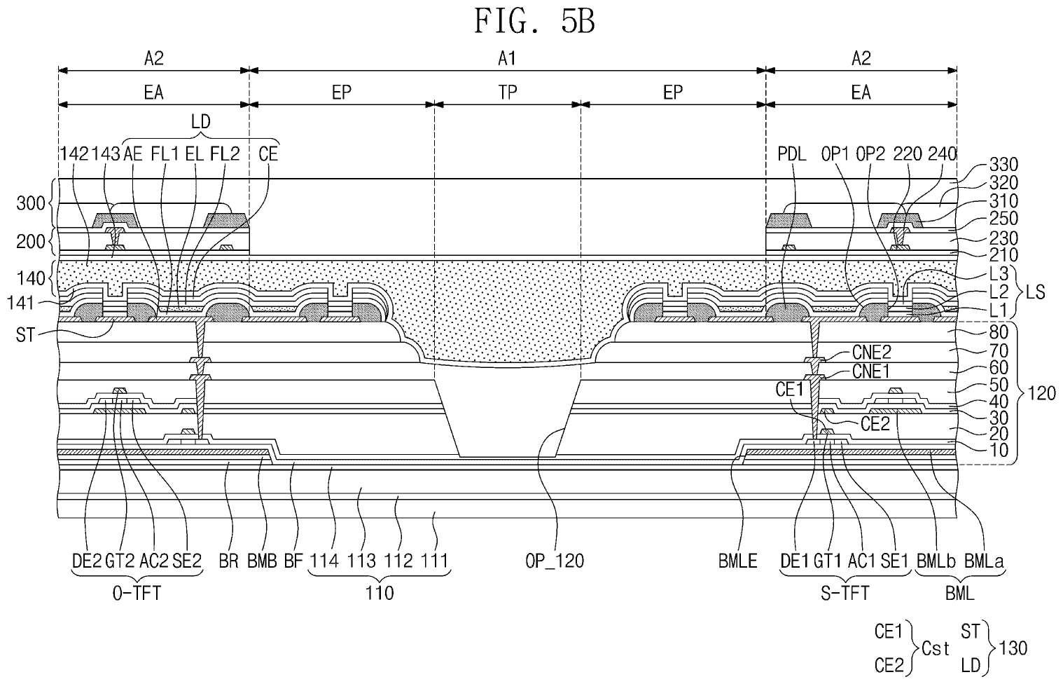

FIG. 5A is a plan view according to an embodiment, and FIG. 5B is a cross-sectional view showing a partial area shown in FIG. 5A. In FIG. 5A, a portion of area XX′ is shown enlarged for easy description, and in FIG. 5B, an area corresponding to FIG. 4A is shown. Hereinafter, the inventive concept will be described with reference to FIGS. 5A and 5B. Meanwhile, like reference numerals are given to like components as those described in FIGS. 1A to 4B, and repeated descriptions are omitted.

In FIG. 5A, a plurality of pixels PX1 and PX2, and conductive patterns 240P constituting the sensor layer 200 are shown. Referring to FIG. 5A, in the display panel DP, the hole MH (see FIG. 3B) may not be provided in the first area A1. Accordingly, some of the pixels PX may also be located in the first area A1. Specifically, the pixel PX is provided in plurality, and the plurality of pixels PX may include a first pixel group PX1 and a second pixel group PX2 located in the first area A1. The first pixel group PX1 may be composed of a plurality of first pixels PX11, PX12, and PX13, and the second pixel group PX2 may be composed of a plurality of second pixels PX21, PX22, and PX23 located in the second area A2. A planar shape of each of the plurality of first pixels PX11, PX12, and PX13 and the plurality of second pixels PX21, PX22, and PX23 shown in FIG. 5A may correspond to the area of light emission from a single light emitting element LD.

The number (a first number) of the plurality of first pixels PX11, PX12, and PX13 located in a prescribed area PA1 may be smaller than the number (a second number) of the plurality of second pixels PX21, PX22, and PX23 located in a prescribed area PA2. Accordingly, the resolution of the first area A1 may be lower than that of the second area A2. The prescribed area PA1 indicated in the first area A1 and the prescribed area PA2 indicated in the second area A2 may have the same shape and area. For example, the first number may be about 8, and the second number may be about 25. However, this is just an example for explaining the difference in resolution, and the first and second numbers are not limited thereto.

Meanwhile, in the present plan view, each of the pixels PX11, PX12, PX13, PX21, PX22, and PX23 may correspond to each light emitting region in which each of the pixels emits light. In addition, in a pixel structure to be described below, the pixels may correspond to sub-pixels. A detailed description thereabout will be provided below.

The plurality of first pixels PX11, PX12, and PX13 may include a first red pixel PX11, a first green pixel PX12, and a first blue pixel PX13. The plurality of second pixels PX21, PX22, and PX23 may include a second red pixel PX21, a second green pixel PX22, and a second blue pixel PX23.

In the first area A1 of the display panel DP, a plurality of transmission regions TP may be defined. The transmission regions TP may be defined to be spaced apart from the first area A1. The forgoing two first red pixels PX11, four first green pixels PX12, and two first blue pixels PX13 may be defined as one group, and at least a portion of the one group may be adjacent to the at least one transmission region TP. As the transmission regions TP are defined in the first area A1, the transmissivity of the first area A1 may be higher than that of the second area A2.

The first area A1 may include the transmission regions TP, and a first sub-area SA1 and a second sub-area SA2 adjacent to the transmission regions TP. The transmissivity of the transmission regions TP may be higher than those of the first sub-area SA1 and the second sub-area SA2.

For example, the first sub-area SA1 may be a portion covered by a division layer 310. In addition, the second sub-area SA2 may be entirely covered by the division layer 310. Accordingly, in the second sub-area SA2 and the first sub-area SA1, the light may not be transmitted, or the transmissivity is lower than that the transmission region TP. In FIG. 5A, different hatchings are given to discriminate the transmission region TP and the first sub-area SA1. In addition, the second sub-area SA2 is differently hatched so as to be discriminated from other transmission regions.

The second sub-area SA2 may be adjacent to the second area A2. For example, the second sub-area SA2 may abut on the boundary between the first area A1 and the second area A2. The second sub-area SA2 may be defined in the first area A1 between the first pixels PX11, PX12, and PX13 and the second pixels PX21, PX22, and PX23. Therefore, the second sub-area SA2 may be adjacent to a pixel group located in the first area A1 and a pixel group located in the second area A2. The area of the second sub-area SA2 may be smaller than that of the transmission region TP.

A boundary area, in which the second pixels PX21, PX22, and PX23 are not located, may be defined even in a portion adjacent to the first area A1 in the second area A2 of the display panel DP. A third sub-area SA3 may be defined in a portion adjacent to the first area A1 in the second area A2. The third sub-area SA3 may abut on the boundary between the first area A1 and the second area A2. The third sub-area SA3 may have the shape connected to the second sub-area SA2 defined in the first area A1.

The pixel definition layer PDL may not be located in the transmission regions TP. The first sub-area SA1 may not overlap the pixel definition layer PDL, but may overlap the division layer 310. The boundary between the transmission region TP and the first sub-area SA1 may include a curve. When the boundaries of the transmission region TP and the first sub-area SA1 are connected, a circular shape may be derived. The second sub-area SA2 located in the first area A1 and the third sensing area SA3 located in the second area A2 may overlap the pixel definition layer PDL. The transmission region TP may overlap neither the pixel definition layer PDL nor the division layer 310. However, this is described as an example, and in the display panel according to an embodiment of the inventive concept, the pixel definition layer PDL may be located in both of the first area A1 and the second area A2, and is not limited to any one embodiment.

The second sub-area SA2 and the first sub-area SA1 are located in the first area A1 adjacent to the second area A2, and the third sensing area SA3 is located in the second area A2 adjacent to the first area A1. An area in which the second sub-area SA2 and the first sub-area SA1 are defined in the first area A1, and an area in which the third sensing area SA3 is defined in the second area A2 may be defined as boundary areas. In the boundary area, the two first red pixels PX11, the four first green pixels PX12, the two first blue pixels PX13 are located adjacent to each other to provide one pixel group, and the one pixel group is covered with the division layer 310 to be adjacent to at least one second sub-area SA2 and/or at least one first sub-area SA1 having relatively lower transmissivity in comparison to the other transmission regions.

For example, the first pixel group PX1 located in the first area A1 may include a connection part pixel group PX1-C and a central part pixel group PX1-M. The central part pixel group PX1-M may be a portion surrounded by the transmission region TP and the first sub-area SA1, etc. The connection part pixel group PX1-C may include a first connection part pixel group PX1-C adjacent to two second transition areas A2, and a second connection part pixel group PX1-C2 adjacent to one second transition area A2. The first connection part pixel group PX1-C1 may be a pixel group located in corner portions in the first area A1, and the second connection part pixel group PX1-C2 may be a pixel group located in vertical and horizontal side portions in the first area A1. The connection part pixel group PX1-C may be a pixel group located in the boundary area, wherein the first connection part pixel group PX1-C1 may be located in corner portions in the boundary area, and the second connection part pixel group PX1-C2 may be located in vertical and horizontal side portions in the boundary area.

In the second area A2, the second red pixels PX21 and the second green pixels PX22 may be alternately arranged one-by-one respectively along a fourth direction DR4 and a fifth direction DR5. In addition, in the second area A2, the second blue pixels PX23 and the second green pixels PX22 may be alternately arranged one-by-one respectively along the fourth direction DR4 and the fifth direction DR5. The fourth direction DR4 may be a direction between the first direction DR1 and the second direction DR2, and the fifth direction DR5 may be a direction crossing with or orthogonal to the fourth direction DR4. On the basis of one second green pixel PX22, the second red pixels PX21 may be spaced apart in the fourth direction DR4, and the second blue pixels PX23 may be spaced apart in the fifth direction DR5.

In the second area A2, the second red pixels PX21 and the second blue pixels PX23 may be alternately arranged one-by-one respectively along the first direction DR1 and the second direction DR2. The second green pixels PX22 may be alternately arranged along the second direction DR2. The first red pixel PX11 may have a larger area than the second red pixel PX21, the first green pixel PX12 may have a larger area than the second green pixel PX22, and the first blue pixel PX13 may have a larger area than the second blue pixel PX23. However, this only shows an example, and the area relationship between the first red, green, and blue pixels PX11, PX12, and PX13, and the second red, green, and blue pixels PX21, PX22, and PX23 is not limited to the forgoing embodiment.

In addition, the first red pixel PX11 may have a different shape from the second red pixel PX21, the first green pixel PX12 may have a different shape from the second green pixel PX22, and the first blue pixel PX13 may have a different shape from the second blue pixel PX23. However, this only illustrated as an example, and the shapes of the first red, green, and blue pixels PX11, PX12, and PX13, may be respectively the same as those of the second red, green, and blue pixels PX21, PX22, and PX23.

The conductive pattern 240P may include a first pattern 240P1 located in the first area A1, and a second pattern 240P2 located in the second area A2. The first pattern 240P1 is located in the transmission region TP. The first pattern 240P1 may include a plurality of mesh lines. The first pattern 240P1 may include a plurality of first mesh lines MS11 extending along the first direction DR1, and a plurality of second mesh lines MS12 extending along the second direction SR2. The first mesh lines MS11 and the second mesh lines MS12 may be electrically connected to provide one sensor pattern, and the sensor layer 200 includes a sensor pattern in plurality to sense an external input applied to the transmission area TP.

The first mesh lines MS11 and the second mesh lines MS12 may be respectively located in a non-overlapping manner with the pixels PX11, PX12, and PX13 corresponding to the light emitting regions. Accordingly, the display characteristics of the display panel may be prevented from being degraded by the sensor layer 200. However, this is illustrated as an example, and in a range in which the visibility of an image is not lowered, some of the first mesh lines MS11 and the second mesh lines MS12 may be arranged in an overlapping manner with some of the pixels PX11, PX12, and PX13. When the first mesh lines MS11 and the second mesh lines MS12 are transparent, the first mesh lines MS11 and the second mesh lines MS12 may be arranged in an overlapping manner with the pixels PX11, PX12, and PX13, and are not limited to any one embodiment.

The second pattern 240P2 is located in the second area A2. The second pattern 240P2 may include a plurality of mesh lines. The second pattern 240P2 may include a plurality of third mesh lines MS21 extending along the fourth direction DR4, and a plurality of fourth mesh lines MS22 extending along the fifth direction DR5. The third mesh lines MS21 and the fourth mesh lines MS22 may be electrically connected to provide one sensor pattern, and the sensor layer 200 includes such a sensor pattern in plurality to sense an external input applied to the second area A2.

Patterns constituting the same electrode between the first pattern 240P1 and the second pattern 204P2 may be electrically connected to each other. For example, mesh lines passing between the second connection part pixel group PX1-C2 are electrically connected with some of the fourth mesh lines MS22. Accordingly, uniform touch sensitivity may be provided to the entire surface of the first area A1 and the second area A2.

Meanwhile, in the inventive concept, the shapes of the mesh lines constituting the first pattern 240P1 and the second pattern 240P2 are shown different from each other. Accordingly, the array shapes of the first pixel group PX1 and the second pixel group PX2 may be different from each other. However, this is illustrated as an example, and the first pixel group PX and the second pixel group PX2 may have the same type of array, and thus the mesh lines constituting the first pattern 240P1 and the second pattern 240P2 may be provided in the same shape. In addition, in the inventive concept, the sensor layer 200 is illustrated to include the conductive pattern 240P configured from the mesh lines. However, the sensor layer 200 may also include a transparent conductive pattern overlapping the plurality of pixel groups PX1 and PX2, and is not limited to any one embodiment.

Meanwhile, a prescribed opening OP_120 overlapping the transmission region TP may be defined in the buffer layer BF included in the circuit layer 120, and in at least some of the plurality of insulation layers 10, 20, 30, 40, 50, 60, 70, and 80. For example, as shown in FIG. 5B, in the first area A1, the opening OP_120 may be defined in a portion in a thickness direction of a second sub-buffer layer BF2, and in the first to fifth insulation layers 10, 20, 30, 40, and 50.

In other words, as a portion in the thickness direction of the second sub-buffer layer BF2 overlapping the transmission region TP, and respective portions of the first to fifth insulation layers 10, 20, 30, 40, and 50 are removed, the transmissivity of the transmission region TP may be enhanced. However, this is illustrated as an example. According to a necessary transmittance of the transmission region TP, the positions of the insulation layers in which openings are defined may be different, and are not limited to any one embodiment.

According to an embodiment, an angle of the side surface facing the transmission region TP in the pixel definition layer PDL is controlled, and thus the organic layers FL1 and FL2, or the second electrode CE may be disconnected between the transmission region TP and the light emitting region EP. Accordingly, the light transmissivity of the transmission region TP may be enhanced. If the functional layers FL1 and FL2 may be disconnected in the second area A2 through the pixel definition layer PDL having the second opening OP2 provided, the display panel according to an embodiment of the inventive concept may have various structures, and is not limited to any one embodiment.

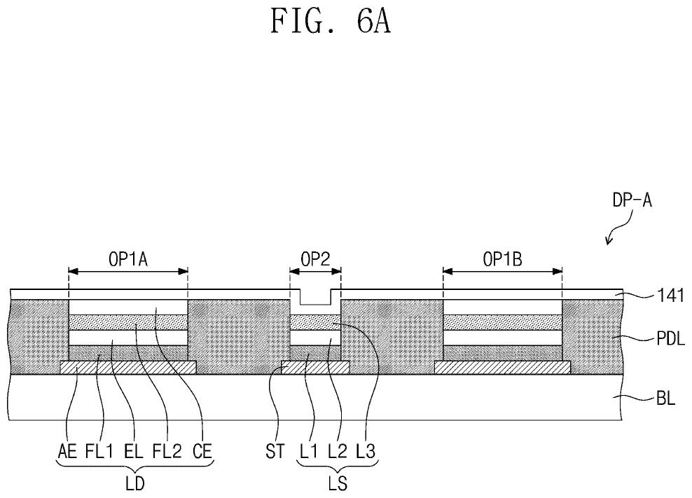

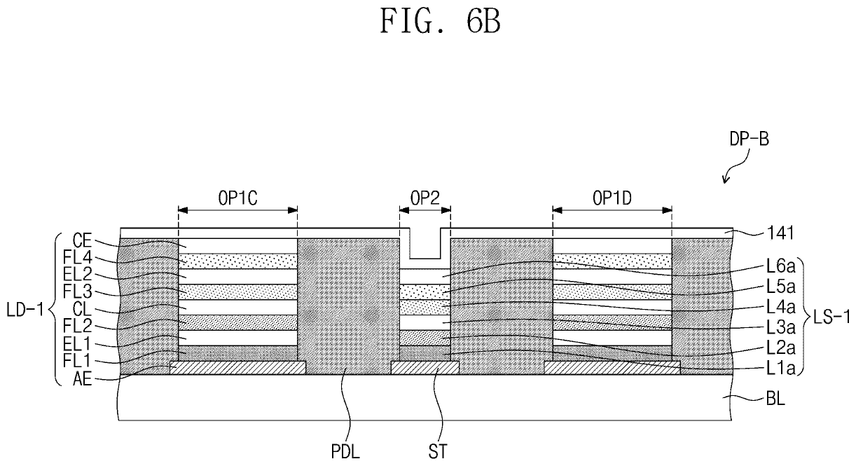

FIGS. 6A and 6B are cross-sectional views of portions of a display panel according to an embodiment of the inventive concept. For easy explanation, layered structures of first openings OP1A, OP1B, OP1C, and OP1D and the second opening OP2 are briefly illustrated in FIGS. 6A and 6B.

As shown in FIG. 6A, in the display panel DP, the light emitting element LD and the laminated structure LS are respectively located in the first openings OP1A and OP1B, and the second opening OP2. FIG. 6A illustrates two adjacent first openings OP1A and OP1B, and the second opening OP2 located therebetween. The base layer BL may correspond to a bottom layer on which the first electrode AE is located.

As described above, the laminated structure LS may be separated from the light emitting element LD by the pixel definition layer PDL. The first layer L1 may correspond to the first functional layer FL1 of the light emitting element LD, the second layer L2 may correspond to the second functional layer FL2 of the light emitting element LD, and the third L3 may correspond to the second electrode CE of the light emitting element LD. In the display panel DP, the second opening OP2 is provided between the first adjacent openings OP1 to disconnect the first and second functional layers FL1 and FL2 and the second electrode CE, and thus blocks the continuity of the first adjacent openings OP1A and OPA2. Accordingly, it is easy to independently drive the light emitting elements LD respectively provided in the first adjacent openings OP1A and OP1B.

Alternatively, as shown in FIG. 6B, the light emitting element LD-1 may include a plurality of light emitting layers EU and EL2. For example, the light emitting element LD-1 may include the first electrode AE, the first functional layer FL1, the first light emitting layer EI1, the second functional layer FL2, a charge generation layer CL, the third functional layer FL3, the second light emitting layer EL2, a fourth functional layer FL4, and the second electrode CE that are sequentially laminated. The first light emitting layer EL1 and the second light emitting layer EL2 may emit light of different colors respectively, or emit light of the same color but different wavelengths respectively. Alternatively, the first light emitting layer EL1 and the second light emitting layer EL2 emit light of the same color and peak wavelength.

The first functional layer FL1 is located between the first light emitting layer EL1 and the first electrode AE. When the first electrode CE is an anode, the first functional layer FL1 may have a hole injection/transport function. Here, the first functional layer FL1 may include at least any one among a hole transport layer, a hole injection layer, or an electron blocking layer. Alternatively, when the first electrode CE is a cathode, the first functional layer FL1 may have an electron hole injection/transport function. Here, the first functional layer FL1 may include at least any one among an electron transport layer, an electron injection layer, or a hole blocking layer.

The second functional layer FL2 is located between the first light emitting layer EL1 and the charge generation layer CL. When the first electrode CE is an anode, the second functional layer FL2 may have an electron injection/transport function. Here, the second functional layer FL2 may include at least any one among an electron transport layer, an electron injection layer, or a hole blocking layer. When the first electrode CE is a cathode, the second functional layer FL2 may have a hole injection/transport function. Here, the second functional layer FL2 may include at least any one among a hole transport layer, a hole injection layer, or an electron blocking layer.

The charge generation layer CL may be located between the first light emitting layer EL1 and the second light emitting layer EL2. When the first electrode AE is an anode and the second electrode AE is a cathode, the charge generation layer CL may provide an electron toward the first light emitting layer EL1 and a hole toward the second light emitting layer EL2. On the contrary, when the first electrode AE is a cathode and the second electrode AE is an anode, the charge generation layer CL may provide a hole toward the first light emitting layer EL1 and an electron toward the second light emitting layer EL2. The charge generation layer CL may be an organic layer including a P-type dopant or an N-type dopant. Alternatively, the charge generation layer CL may be an organic layer including both of a P-type dopant and an N-type dopant. In addition, the charge generation layer CL is shown as a single layer, but may have a laminate structure including a plurality of layers. If providing charges to the first light emitting layer EL1 and the second light emitting layer EL2, the charge generation layer CL according to an embodiment of the inventive concept may be provided in various types and is not limited to any one embodiment.

The third functional layer FL3 is located between the second light emitting layer EL2 and the charge generation layer CL. When the second electrode CE is a cathode, the third functional layer FL3 may have a hole injection/transport function. Here, the third functional layer FL3 may include at least any one among a hole transport layer, a hole injection layer, or an electron blocking layer. Alternatively, when the second electrode CE is an anode, the third functional layer FL3 may have an electron injection/transport function. Here, the third functional layer FL3 may include at least any one among an electron transport layer, an electron injection layer, or an hole blocking layer.

The fourth functional layer FL4 is located between the second light emitting layer EL2 and the second electrode CE. When the second electrode CE is a cathode, the fourth functional layer FL4 may have an electron injection/transport function. Here, the fourth functional layer FL4 may include at least any one among an electron transport layer, an electron injection layer, or an hole blocking layer. Alternatively, when the second electrode CE is an anode, the fourth functional layer FL4 may have a hole injection/transport function. Here, the fourth functional layer FL4 may include at least any one among a hole transport layer, a hole injection layer, or an electron blocking layer.

According to an embodiment, a laminated structure LS-1 provided in the second opening OP2 may be located on the blocking electrode ST and include first to sixth layers L1a, L2a, L3a, L4a, L5a, and L6a. The first to sixth layers L1a, L2a, L3a, L4a, L5a, and L6a may be respectively provided in the processes of providing the first functional layer FI1, the second functional layer FL2, the charge generation layer CL, the third functional layer FL3, the fourth functional layer FI4, and the second electrode CE. In other words, the first to sixth layers L1a, L2a, L3a, L4a, L5a, and L6a may be provided with the same respective materials as those of the first functional layer FI1, the second functional layer FL2, the charge generation layer CL, the third functional layer FL3, the fourth functional layer FI, and the second electrode CE. Meanwhile, this is illustrated as an example. In the light emitting elements LD and LD-1 according to an embodiment of the inventive concept, the number of light emitting layers EL, EL1, and EL2 may change in various ways, and the number of the charge generation layers CL may also change in various ways. The embodiments of inventive concept are not limited to any one embodiment.

Meanwhile, the laminated structure LS-1 may have a different laminate structure from the light emitting element LD-1. For example, in the light emitting element LD-1, when the charge generation layer CL is provided as a laminate structure including an n-type layer and a p-type layer, the first functional layer FL1, the second functional layer FL1, the n-type layer of the charge generation layer CL, and the third functional layer FL3 are provided through an open mask, and the p-type layer of the charge generation layer CL and the fourth functional layer FL4 may be patterned and provided through a fine metal mask (FMM). In this case, the layers provided through the FMM may not be provided in the second opening OP2, and the layers provided through the open mask may be provided by being disconnected from the first openings OP1C and OP1D by the second opening OP2. Accordingly, in the laminated structure LS-1, the fifth layer L5a to be provided together with the fourth functional layer FL4 may be omitted. In addition, in the fourth layer L4a provided together with the charge generation layer CL, a portion corresponding to the p-type layer may be omitted and only a portion corresponding to the n-type may be included. In other words, in the light emitting element LD-1, the layers corresponding to the layer provided through the open mask may be provided in the second opening OP2. Accordingly, when the light emitting element LD-1 is provided using both the open mask and FMM, the laminated structure LS-1 may be provided with only layers corresponding to the layer provided through the open mask and not include a layer corresponding to the layer provided through the FMM. Accordingly, the laminated structure LS-1 may have a different laminate structure from the light emitting element LD-1.

In addition, according to an embodiment, it is illustrated that the first functional layer FL1, the second functional layer FI2, the charge generation layer CL, the third functional layer FI, the fourth functional layer FI, and the second electrode CE are not provided on the pixel definition layer PDL, but this is for easy explanation. As shown in FIG. 4A, at least some of the first functional layer FL1, the second functional layer FI, the charge generation layer CL, the third functional layer FI3, the fourth functional layer FI4, and the second electrode CE may be located on the pixel definition layer PDL, and are not limited to any one embodiment. However, even though located on the pixel definition layer PDL, the first functional layer FL1, the second functional layer FI2, the charge generation layer CL, the third functional layer FI3, the fourth functional layer FI4, and the second electrode CE may be disconnected from the laminated structure LS by the second opening OP2.

According to an embodiment, the first to fourth functional layers FL1, FL2, FL3, and FL4 and the charge generation layer CL are disconnected by the second opening OP to be provided independently in each of the first openings OP1C and OP1D. In other words, in the first to fourth functional layers FL1, FL2, FL3, and FL4 and the charge generation layer CL, the continuity of the first openings OP1C and OP1D may be blocked by the second opening OP. Accordingly, an electrical signal may be prevented from being delivered between the adjacent light emitting elements LD and LD-1 through the first to fourth functional layers FL1, FL2, FL3, and FL4 and the charge generation layer CL. Accordingly, each pixel may be smoothly driven independently, and thus a high resolution panel may also be stably driven.

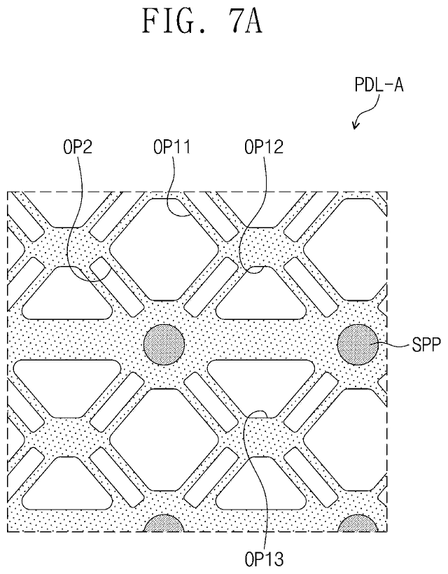

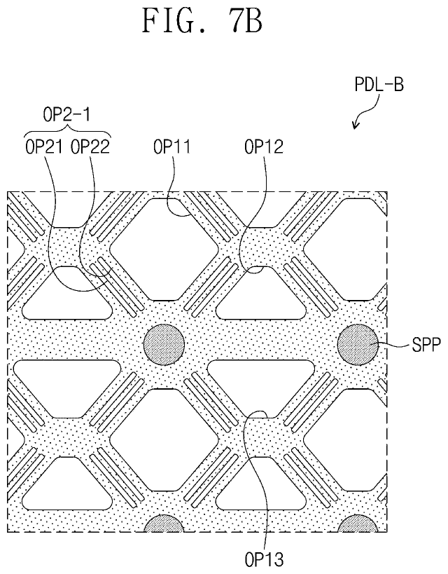

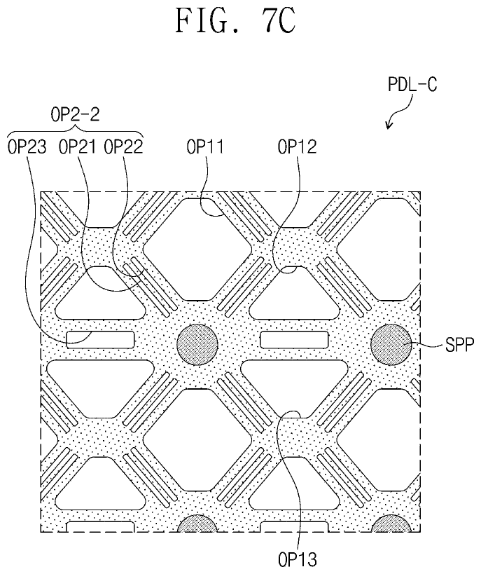

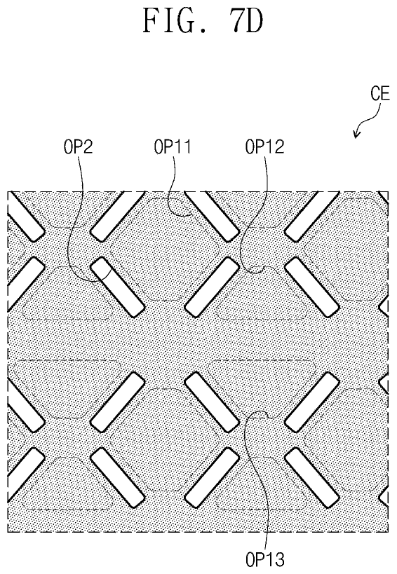

FIGS. 7A to 7D are plan views of partial areas of a display panel according to an embodiment of the inventive concept. In FIGS. 7A to 7D, some elements are omitted for easy explanation.

As shown in FIG. 7A, the first openings OP11, OP12, and OP13 and the second opening OP2 defined in the pixel definition layer PDL-A may be arranged to be spaced apart from each other. The pixel definition layer PDL-A is shown by dots for easy explanation. According to an embodiment, the first openings OP11, OP12, and OP13 may include first to third light emitting openings OP11, OP12, and OP13 with different shapes. Each of the second and third light emitting openings OP12 and OP13 are shown in shapes similar to a trapezoid and in different sizes. The first light emitting opening OP11 is illustrated in a shape similar to a hexagon. Meanwhile, this is illustrated as an example, and the first to third openings OP11, OP12, and OP13 may respectively have other shapes, or have the same shape, and is not limited to any one embodiment.

Meanwhile, a display panel according to an embodiment may further include a spacer SPP. The spacer SPP may be provided in plurality, and be arranged to be spaced apart from each other on the pixel definition layer PDL-A. The spacer SPP may support a mask during patterning the light emitting layer EL (see FIG. 4A). The spacer SPP may be further included in the display panel, and thus prevent the display panel from being damaged by the mask. Meanwhile, this is illustrated as an example, and, according to an embodiment of the inventive concept, the spacer SPP may be omitted.

Alternatively, as shown in FIG. 7B, the second openings OP2-1 defined in the pixel definition layer PDL-B may include a plurality of sub-openings OP21 and OP22. The second opening OP2-1 may include the first sub-opening OP21 and the second sub-opening OP22. The first sub-opening OP21 and the second sub-opening OP22 may have the same shape and be arranged in parallel, and be located between the same first openings OP11, OP12, and OP13. According to an embodiment, the first sub-opening OP21 and the second sub-opening OP22 may increase the possibility of disconnection of the organic layers or the common electrode, and prevent reduction in visibility by miniaturizing the second opening OP2-1.

Alternatively, as shown in FIG. 7C, the second opening OP2-2 defined in a pixel definition layer PDL-C may also include first to third sub-openings OP21, OP22, and OP23. The third sub-opening OP23 may be located between the second and third light emitting openings OP12 and OP13. The third sub-opening OP23 is illustrated to have a larger area than the first and sub-openings OP21 and OP22. The pixel definition layer PDL-C provides the second openings OP2-2 including a plurality of the sub-openings OP21, OP22, and OP23, and thus an independent light emitting element may be provided in each of the light emitting openings OP11, OP12, and OP13.

FIG. 7D is a plan view of the second electrode CE. For easy explanation, FIG. 7D shows the second electrode CE provided on the pixel definition layer PDL-A corresponding to FIG. 7A. As shown in FIG. 7D, the second electrode CE may overlap the first openings OP11, OP12, and OP13, and be disconnected in the second openings OP2. In addition, the second openings OP2 are defined to be spaced apart from each other, and thus the second electrode CE has an integrated shape to overlap all the first openings OP11, OP12, and OP13, but to be removed only in a region overlapping the second openings OP2.

Accordingly, a direct flow of a current between two adjacent light emitting openings OP11, OP12, and OP13 may be blocked through the second electrode CE, and thus independent driving may be easily achieved. FIG. 7D only shows the second electrode CE, but the shapes of various layers provided through an open mask and disconnected through the second openings OP2 may be correspond to this. For example, the foregoing first to fourth functional layers FL1, FL2, FL3, and FL4, or the charge generation layer CL may have the shape corresponding to that of the second electrode CE.

According to an embodiment of the inventive concept, a disconnection type of the organic layers or the second electrode CE may be designed in various ways by setting the shape and array of the second openings P2, OP2-1, and OP2-2 in various ways. Accordingly, organic layers or the second electrode CE between adjacent light emitting openings may be disconnected without a patterning process using a separate mask, and thus layer continuity and a current flow may be easily blocked.

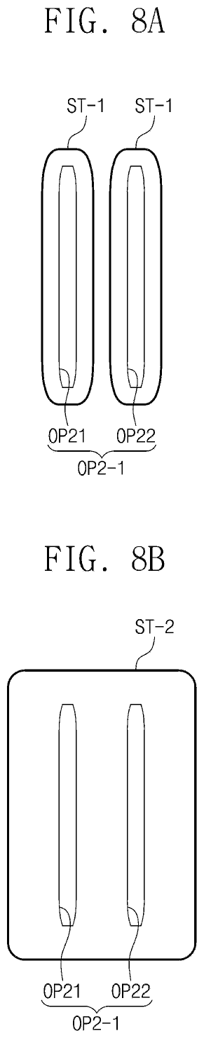

FIGS. 8A and 8B are plan views of some components of a display panel according to an embodiment of the inventive concept. FIGS. 8A and 8B illustrate a blocking electrode and a second opening overlapping therewith. Hereinafter, the inventive concept will be described with reference to FIGS. 8A and 8B. Meanwhile, like reference numerals are given to like components as those described in FIGS. 1 to 7D, and repeated descriptions are omitted.

As shown in FIG. 8A, the blocking electrode ST-1 is provided in plural to be located in each of the sub-openings OP21 and OP22. The blocking electrodes ST-1 respectively overlap the first and second sub-openings OP21 and OP22, and are arranged to be spaced apart from each other. The blocking electrodes ST-1 have the shapes corresponding to the second openings OP-2 and are electrically floated.

Alternatively, as shown in FIG. 8B, a blocking electrode ST-2 is provided in single to be arranged overlapping all the first and second sub-openings OP21 and OP22. Here, the blocking electrode ST-2 may have a different shape from the second opening OP2-1. The blocking electrode ST-2 may have the shape spaced apart from or a lattice shape connected with another adjacent second opening OP2-1, and is not limited to any one embodiment.

According to an embodiment of the inventive concept, the blocking electrodes ST-1 and ST-2 may have the shape corresponding to the second opening OP2-1 or a separate independent shape. The blocking electrodes ST-1 and ST-2 overlap the second opening OP2-1 in a plan view, and when spaced apart from the first electrode AE, may be designed in various shapes, and is not limited to any one embodiment.

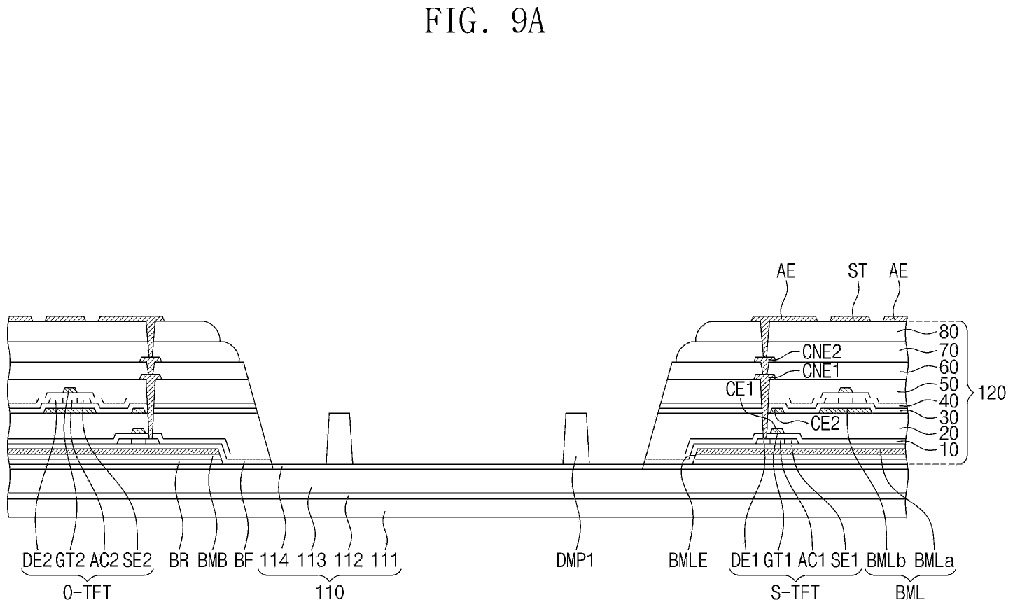

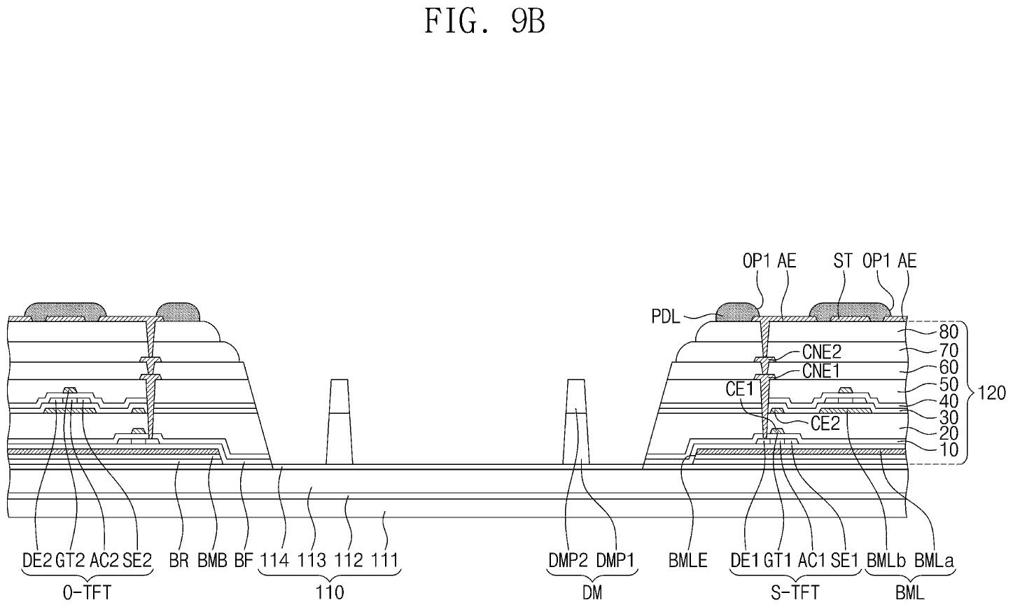

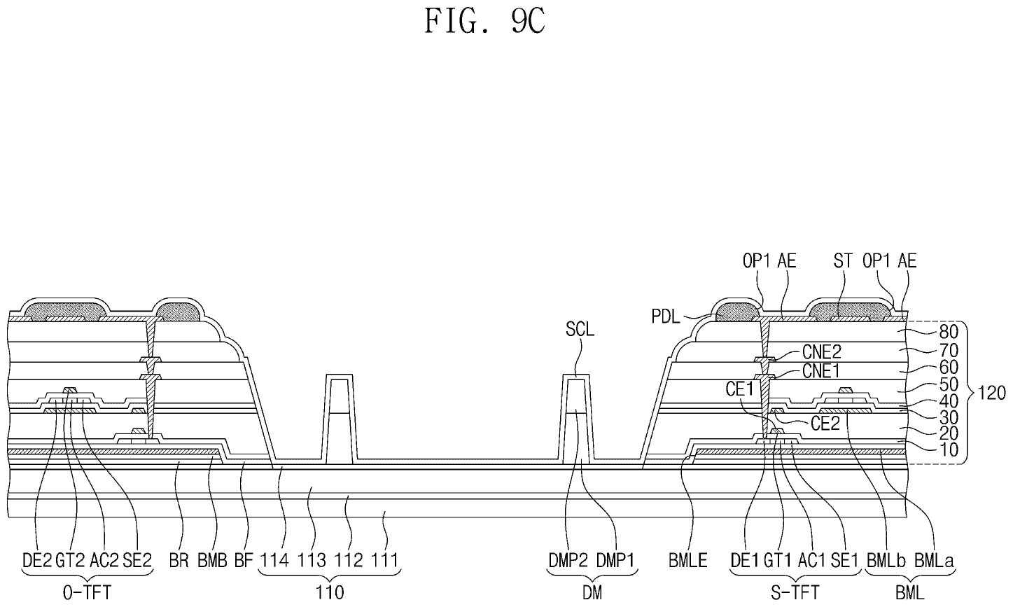

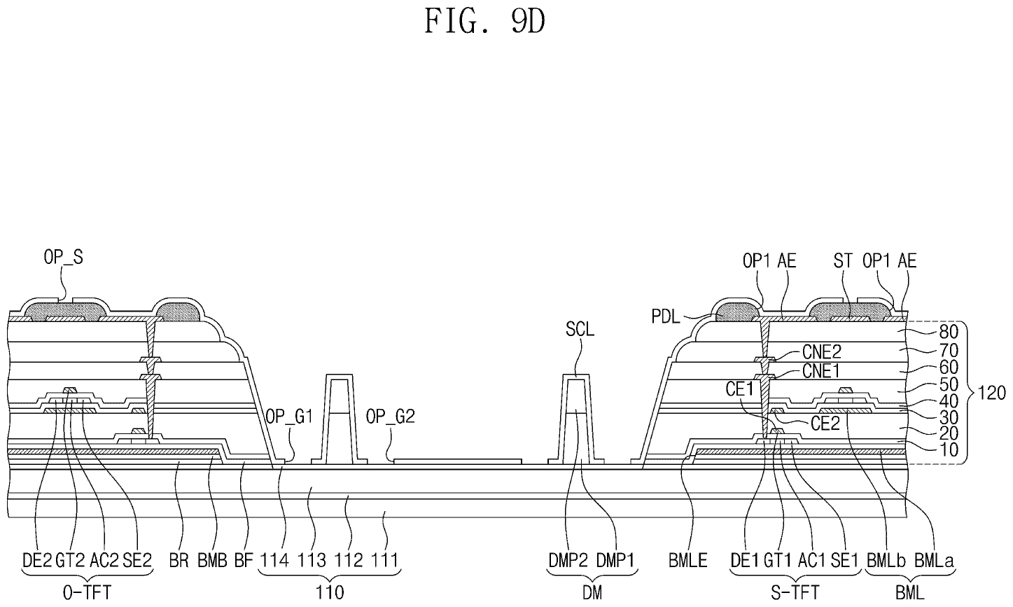

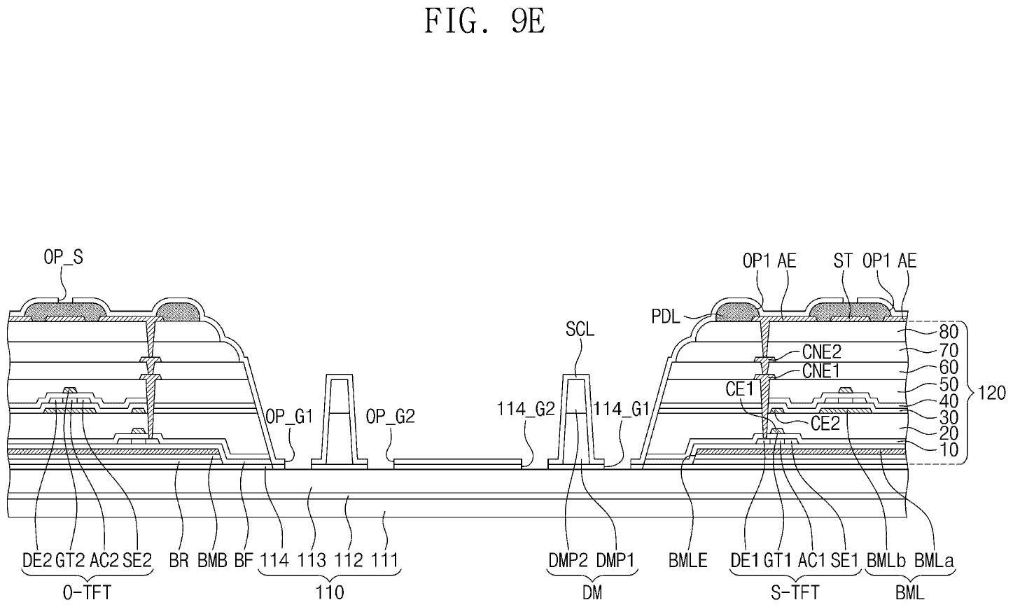

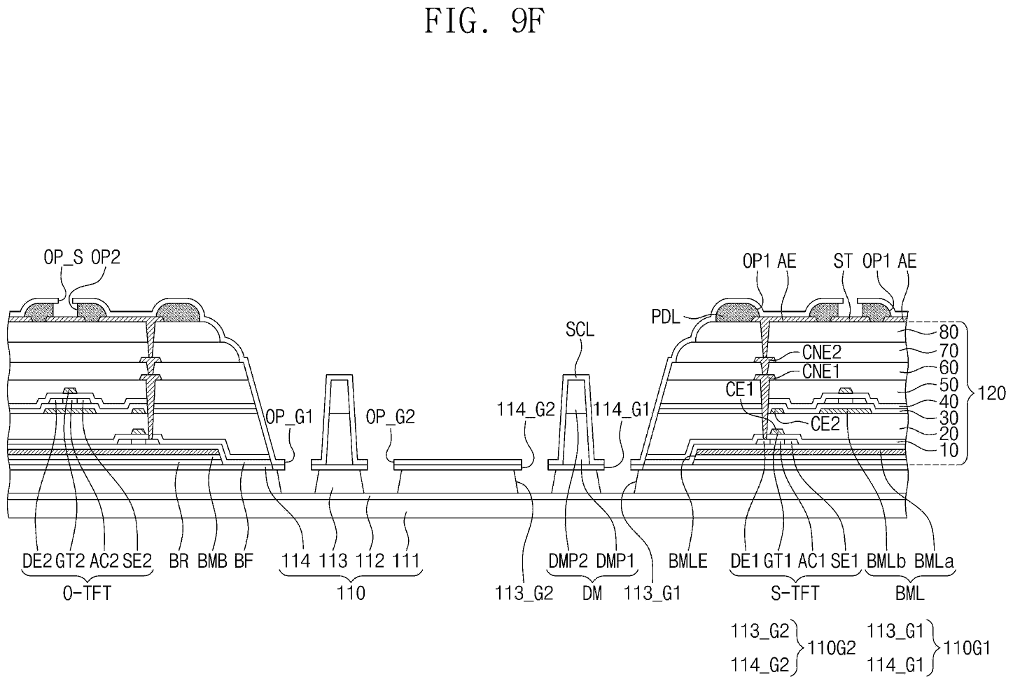

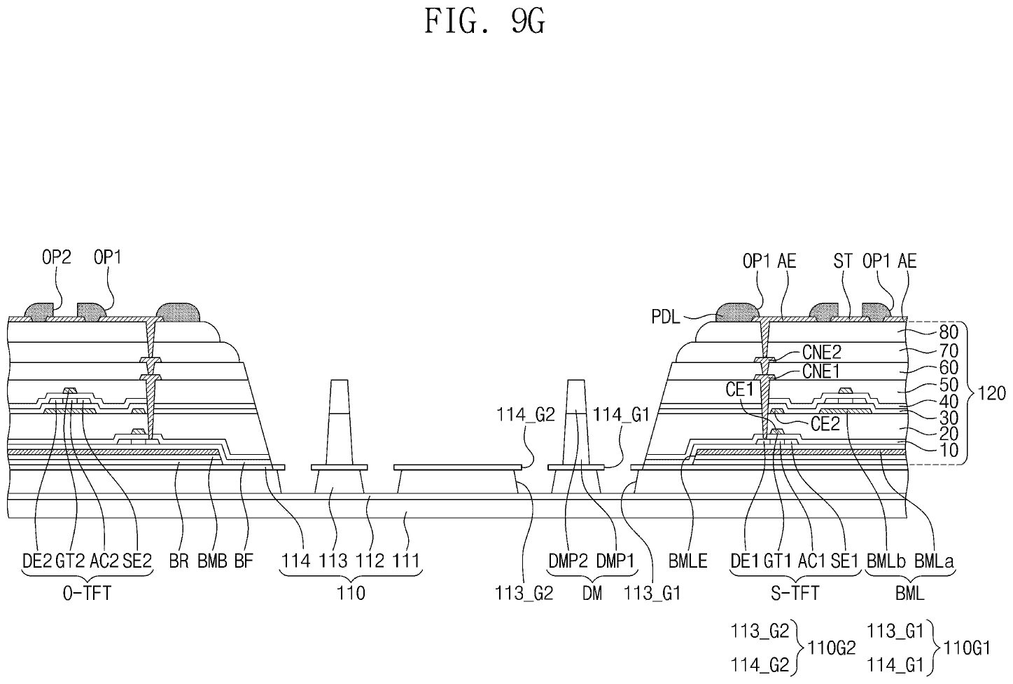

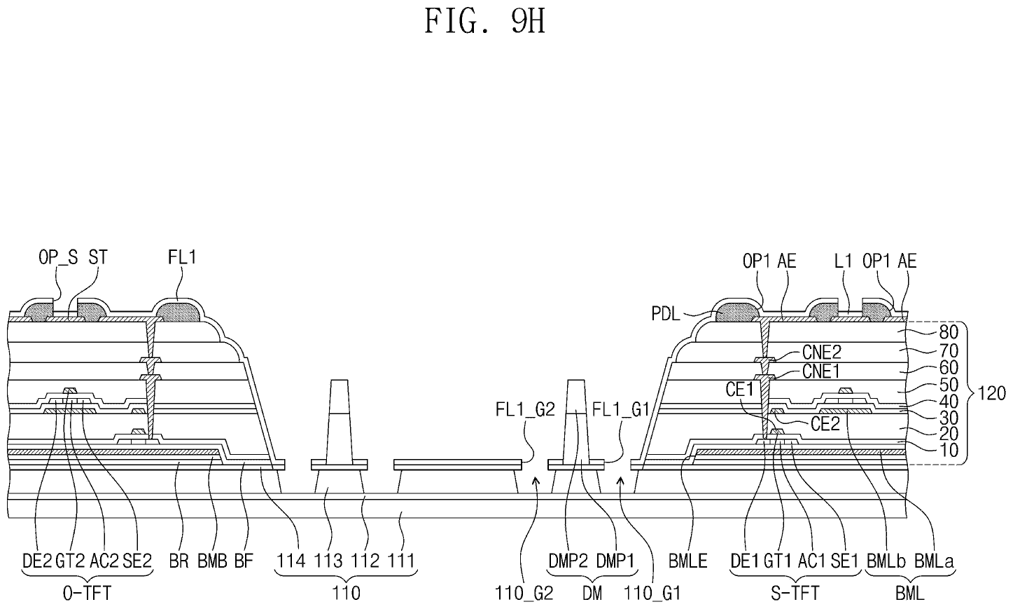

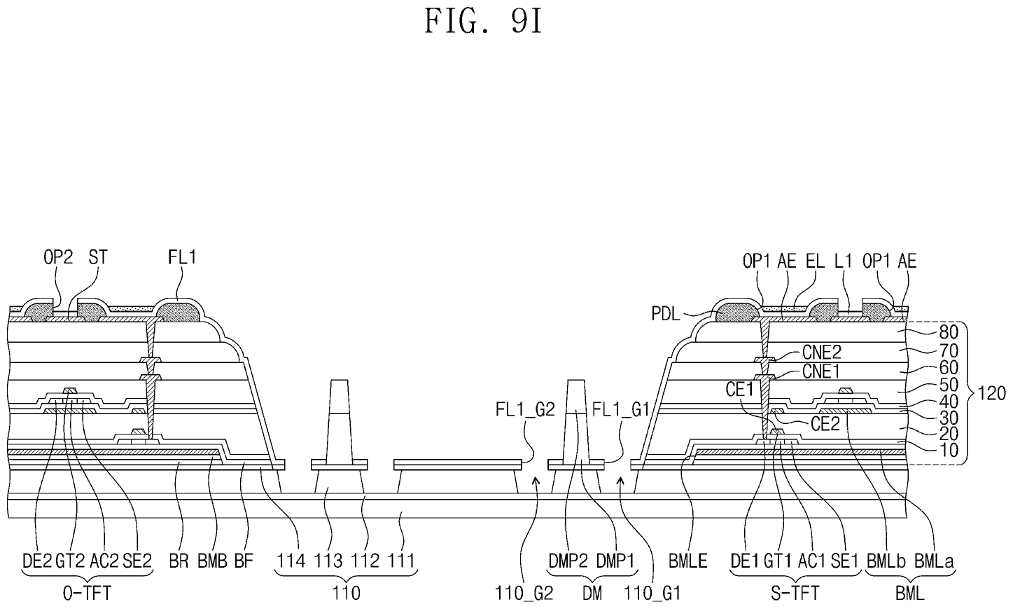

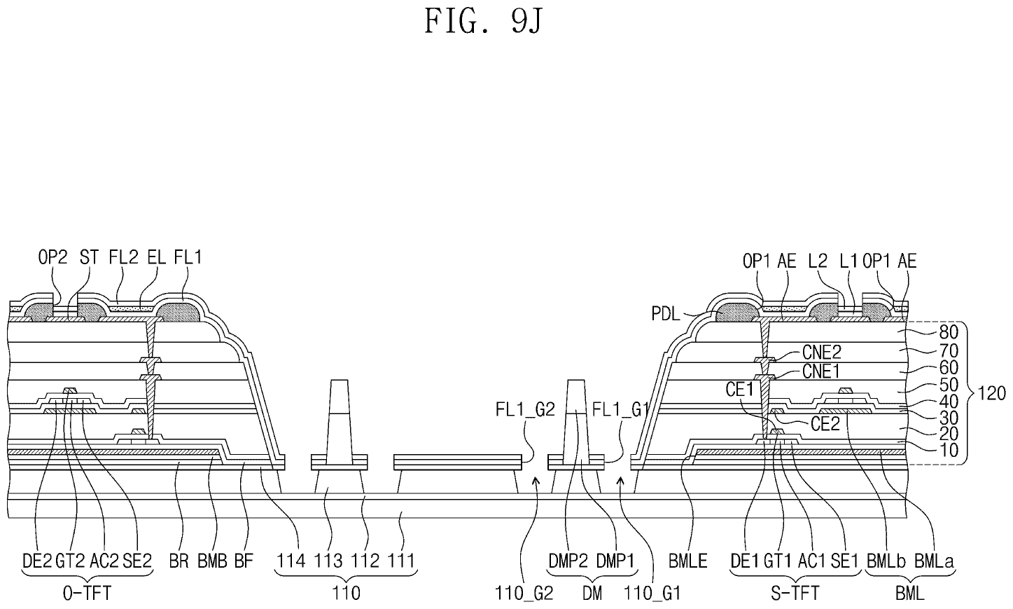

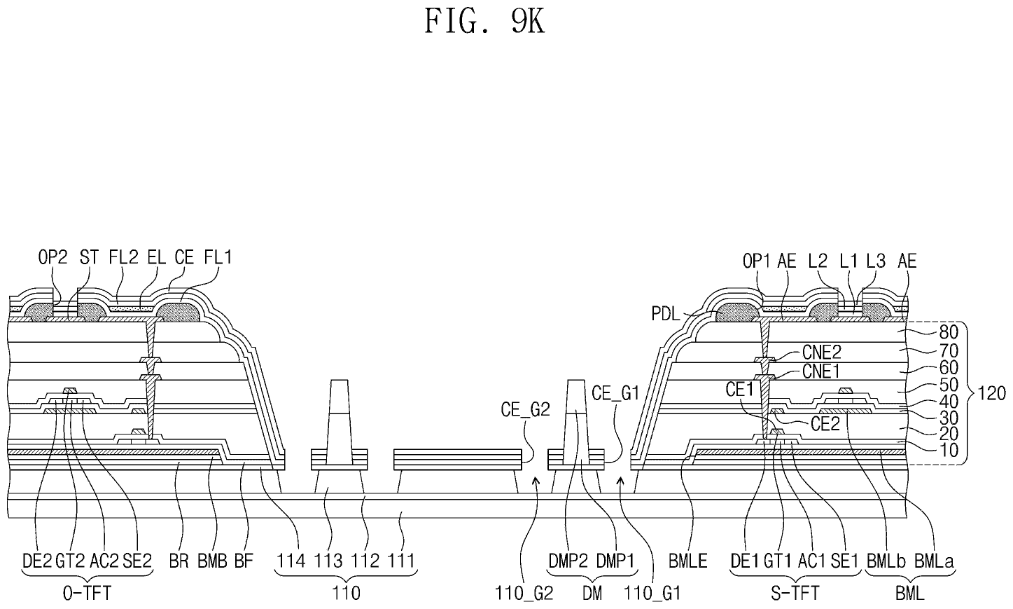

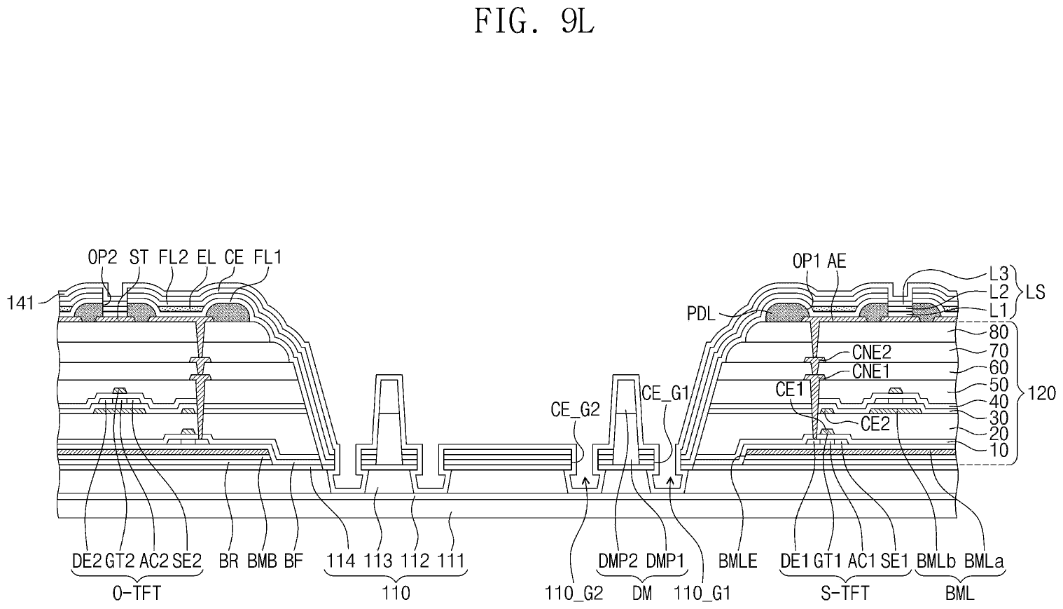

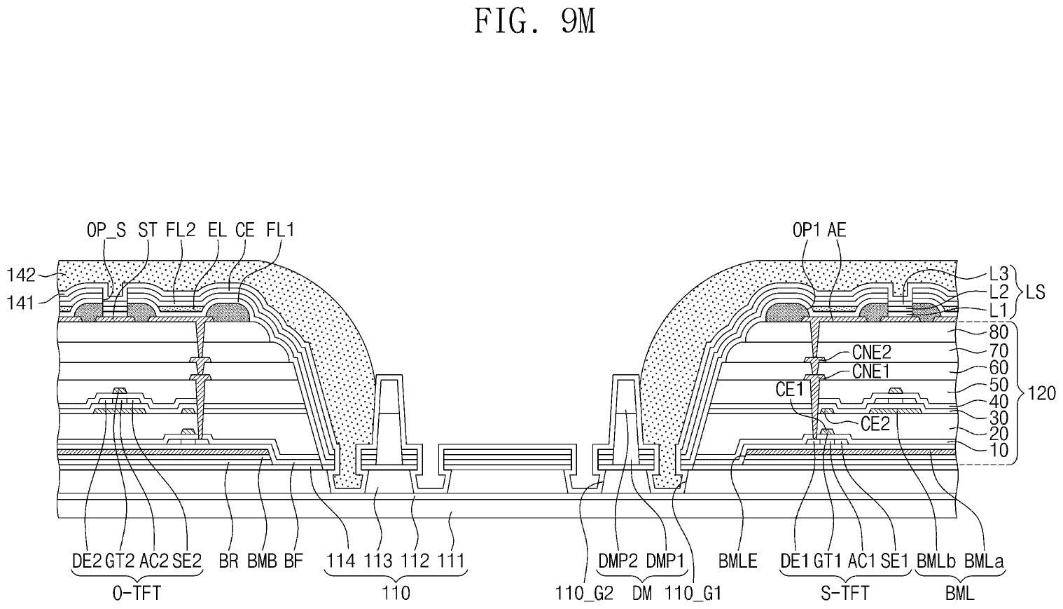

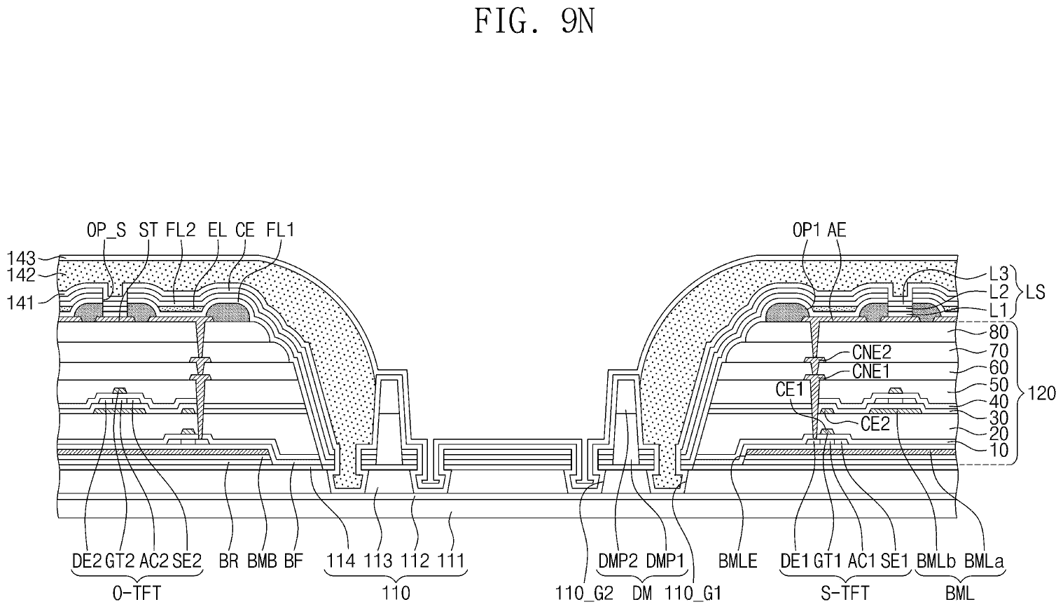

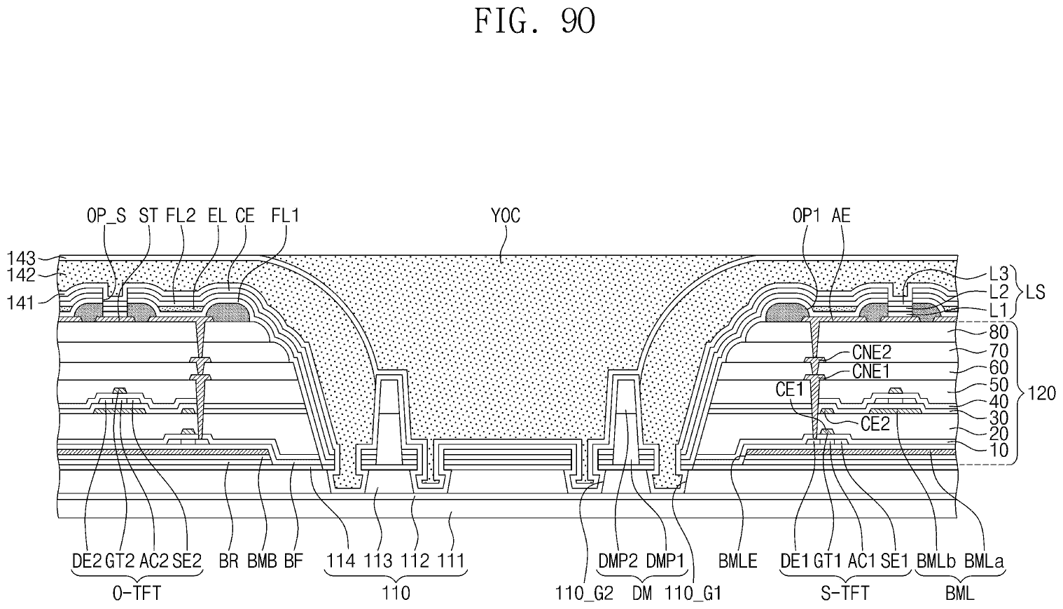

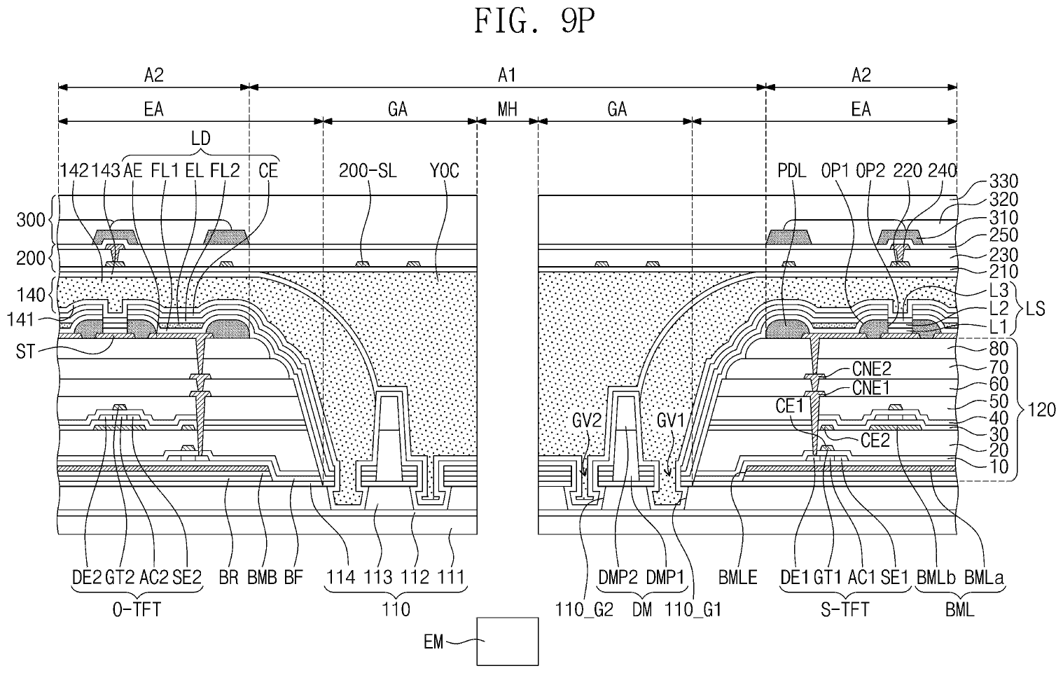

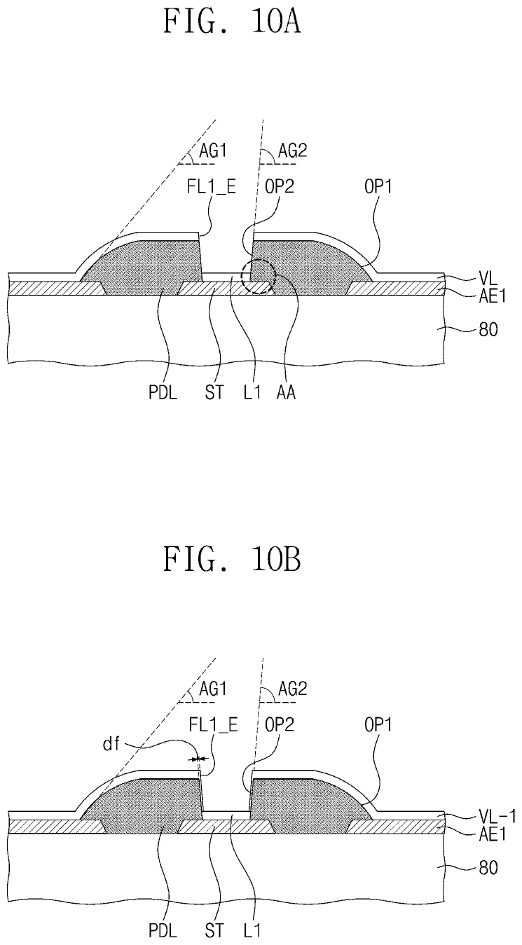

FIGS. 9A to 9P are cross-sectional views for explaining a manufacturing method of a display panel according to an embodiment of the inventive concept. FIGS. and 10B are cross-sectional views of portions of a display panel according to an embodiment of the inventive concept. Hereinafter, aspects of an embodiment of the inventive concept will be described in more detail with reference to FIGS. 9A to 10B.

As shown in FIG. 9A, the first electrode AE and the blocking electrode ST are provided on the substrate 110 on which the circuit layer 120 is provided. The first electrode AE and the blocking electrode ST may be provided by patterning the conductive layer. The first electrode AE and the blocking electrode ST may be substantially simultaneously provided through one mask. Accordingly, the first electrode AE and the blocking electrode ST may be provided with the same material on the same layer. Accordingly, the blocking electrode ST may be easily provided without a separate process, and thus the entire process becomes relatively simplified and a process cost may be relatively reduced.

Here, a first layer DMP1 of the dam part may be provided. According to an embodiment, the first layer DMP1 of the dam part may be substantially simultaneously provided with at least any one of the first to eighth insulation layers 10 to 80. However, this is illustrated as an example. The first layer DMP1 of the dam part may be provided through subsequent processes, and is not limited to any one embodiment.

Then, as shown in FIG. 9B, the pixel definition layer PDL is provided. The pixel definition layer PDL may be provided by patterning the insulation layer. Here, in the pixel definition layer PDL, the first opening OP1 may be defined to expose the first electrode AE. The blocking electrode ST may be covered by the pixel definition layer PDL.

Then, as shown in FIG. 9C, a sacrificial layer SCL is provided. The sacrificial layer SCL may be provided on the entire surface of the substrate 110, Accordingly, the sacrificial layer SCL covers the second intermediate barrier layer 114, the dam part DM, the pixel definition layer PDL, and the first electrode AE covered by the first opening OP1.

The sacrificial layer SCL may be provided by depositing an inorganic material. The inorganic material may include a conductive oxide. For example, the sacrificial layer SCL may include a transparent conductive oxide such as indium gallium zinc oxide (IGZO), indium zinc oxide (IZO), or indium tin oxide (ITO).

Then, as shown in FIG. 9D, a plurality of openings OP_S, OP_G1, and OP_G2 are provided by patterning the sacrificial layer SCL. In the first area A1, two openings OP_G1 and OP_G2 are provided with the dam part DM interposed therebetween. The two openings OP_G1 and OP_G2 may be openings for providing the groove patterns GV1 and GV2 to be described below.

In the second area A2, the opening OP_S is provided to expose a portion of the pixel definition layer PDL. The opening OP_S may be provided in an area overlapping the blocking electrode ST in a plan view. The opening OP_S may be an opening for providing the second opening OP2 to be described blow.

Then, as shown in FIG. 9E, a plurality of openings 114_G1 and 114_G2 may be provided by patterning the second intermediate barrier layer 114. The openings 114_G1 and 114_G2 may be provided using the sacrificial layer SCL as a mask through an etching process. The openings 114_G1 and 114_G2 may have the size corresponding to that of the openings OP_G1 and OP_G2 provided in the sacrificial layer SCL. Here, the pixel definition layer PDL includes a different material from the second intermediate barrier layer 114, and thus a portion exposed by the opening OP_S in the pixel definition layer PDL may not be etched.

Then, as shown in FIG. 9F, the groove parts 110_G1 and 110_G2 may be provided by patterning the second sub-base layer 113. Specifically, the second sub-base layer 113 is etched using the sacrificial layer SCL as a mask, and thus the openings 110_G1 and 110_G2 may be provided in the second sub-base layer 113. Each of the groove parts 110_G1 and 110_G2 may be defined by each of the openings 114_G1 and 114_G2 provided in the second intermediate barrier layer 114, and each of the openings 113_G1 and 113_G2 provided in the second sub-base layer 113.

Here, the pixel definition layer PDL may also be patterned. The pixel definition layer PDL may be etched using the sacrificial layer SCL as a mask. Accordingly, the second opening OP2 may be provided in the pixel definition layer PDL. The pixel definition layer PDL is provided with an organic material, and thus may be etched together with the second sub-base layer 113 in the same process.

The etchings of the second sub-base layer 113 and the pixel definition layer PDL may be isotropic etching. Accordingly, the second sub-base layer 113 and the pixel definition layer PDL may be undercut for the sacrificial layer SCL. Accordingly, top sizes of the openings 113_G1 and 113_G2 provided in the second sub-base layer 113 may be larger than those of the openings OP_G1 and OP_G2 provided in the sacrificial layer SCL. In addition, the size of the second opening OP2 provided in the pixel definition layer PDL2 may be larger than that of the opening OP_S provided in the sacrificial layer SCL.

Here, the blocking electrode ST may serve as an etching stopper. In other words, in the process in which the pixel definition layer PDL is etched using the opening OP_S of the sacrificial layer SCL as a mask, the blocking electrode ST is not etched. Accordingly, when providing the second opening OP2, the insulation layer 80 located under the bottom of the blocking electrode ST may not be etched and protected by the blocking electrode ST. Accordingly, the process reliability may be enhanced.

Then, as shown in FIG. 9G, the sacrificial layer SCL is removed. A portion of the first intermediate barrier layer 112 may be exposed by the groove parts 110_G1 and 110_G2. In addition, a portion of the blocking electrode ST may be exposed by the second opening OP2.

Then, as shown in FIG. 9H, the first functional layer FL1 is provided. The first functional layer FL1 may be provided through an evaporation process. The first functional layer FL1 may be provided on the entire surface of the substrate 110. Here, the groove parts 110_G1 and 110_G2 provided in the substrate 110 have an undercut shape, and thus the functional layer FL1 may be disconnected with the groove parts 110_G1 and 110_G2 interposed therebetween. According to an embodiment, a portion of an evaporation material may enter the groove parts 110_G1 and 110_G2 to provide inorganic patterns. However, the patterns may be provided as an independent pattern disconnected from the first functional layer FL1 provided around the groove parts 110_G1 and 110_G2. Accordingly, the first functional layer FL1 may be provided in a discontinuous type in the first area A1 through the groove parts 110_G1 and 110_G2. The first functional layer FL1 is disconnected in the groove parts 110_G1 and 110_G2 to provide the ends FL1_G1 and FL1_G2.

Here, the first functional layer FL1 may also be provided in a discontinuous type in the second area A2 through the second opening OP2. FIG. 10A shows the pixel definition layer PDL, the first electrode AE, the blocking electrode ST, and a deposition layer VL. The deposition layer VL may be a hole transport layer, an electron transport layer, or a charge generation layer. For example, the deposition layer VL may be at least one among the first functional layer FL1, the second functional layer FL2, the charge generation layer CL, the third functional layer FI3, or the fourth functional layer FL4. According to an embodiment, the deposition layer VL may correspond to the first functional layer FL1

Referring to FIG. 10A, in the pixel definition layer PDL, an inclination angle AG1 (hereinafter, a first angle) of the side surface defining the first opening OP1, and an inclination angle AG2 (hereinafter, a second angle) of the side surface defining the second opening OP2 may be different from each other. The second angle AG2 may be provided larger than the first angle AG1.

For example, the first angle AG1 may be smaller than about 50 degrees. Like the first functional layer FL1, a layer provided through the evaporation process may be provided in a type that maintains the continuity in the side surface having the first angle AG1 of the pixel definition layer PDL. Accordingly, the first functional layer FL1 extends to the side surface of the pixel definition layer PDL from the top surface of the first electrode AE exposed by the first opening OP1, and thus has an integrated form having continuity.

Unlike this, the second angle AG2 may be about 50 to about 90 degrees. As the inclination angle of the side surface of the pixel definition layer PDL increases, the first functional layer FI1 may be disconnected in the side surface of the pixel definition layer PDL. Accordingly, the first functional layer FL1 may not be provided in the side surface having the second angle AG2 of the pixel definition layer PDL. In the second opening OP2, the first layer L1 may be provided to be separated from the first functional layer. The first layer L1 may be provided in an independent pattern from the first functional layer FL1. However, this is illustrated as an example, and as the size of the second opening OP2 becomes smaller, the first layer L1 may not be provided.

The pixel definition layer PDL covers the blocking electrode ST except for the second opening OP2. Referring to an AA portion, a portion not exposed by the second opening OP2 in the blocking electrode ST may contact the pixel definition layer PDL. Accordingly, at least a portion of the side surface and the top surface of the blocking electrode ST may be covered by the pixel definition layer PDL.

According to an embodiment of the inventive concept, the second opening OP2 is provided in the pixel definition layer PDL, and thus a disconnected area may be provided in the first functional layer FL1 without an additional structure. Accordingly, an issue such as a phenomenon of a side surface current leakage caused by sharing the first functional layer FL1 between two adjacent light emitting regions, or an increase in power consumption caused by the phenomenon may be improved. In addition, independent driving may be easily achieved for each pixel. Therefore, the electrical reliability of the display panel may be enhanced.

As described above, the second opening OP2 may be provided through the sacrificial layer SCL. In other words, the second opening OP2 may be provided together during the providing the groove parts 110_G1 and 110_G2. Accordingly, the disconnection structure of the first functional layer FL1 may be provided without a separate process, and thus the entire process becomes relatively simplified and a process cost may be relatively reduced.

Referring to FIG. 10A, the deposition layer VL may have a disconnection structure by not being provided on an inclination surface defining the second opening OP2 in the pixel definition layer PDL. Unlike this, referring to FIG. 10B, a deposition layer VL-1 according to an embodiment of the inventive concept may also have the thickness of a thin film along the inner walls of the second opening OP2. According to an embodiment, the thickness df of the deposition layer VL-1 is thinner than that of a portion positioned on the pixel definition layer PDL. The thickness df of the deposition layer VL-1 may make a charge or the like difficult to be delivered, and substantially make an effect corresponding to disconnection in terms of a charge transfer. According to an embodiment of the inventive concept, as the second angle AG2 is set to about 50 degrees or larger, the deposition layer VL-1 may be provided, the thickness of which is as thin as the deposition layer VL is disconnected or electrically disconnected. In other words, the deposition layers VL and VL-1 are provided in a disconnection structure or with a thin-film thickness, and thus a display panel may be provided which has an electrically disconnected structure or an independently drivable structure between adjacent light emitting regions.

According to an embodiment of the inventive concept, not only the disconnected deposition layer VL, but also a deposition layer VL-1 having a thin film as thin as electrically disconnected may be easily provided, and thus independent driving is enabled between adjacent light emitting regions. Accordingly, an issue such as a phenomenon of a side surface current leakage caused by sharing the first functional layer FL1 between two adjacent light emitting regions, or an increase in power consumption caused by the phenomenon may be improved. In addition, independent driving may be easily achieved for each pixel. Therefore, the electrical reliability of the display panel may be enhanced.

Referring back to FIG. 9I, the light emitting layer EL is then provided. The light emitting layer EL may be optionally provided only in the first opening OP1. The light emitting layer EL may be provided through a printing process or an inkjet process. Then, as shown in FIG. 9J, the second functional layer FL2 is provided. The second layer FL2 may be provided in an evaporation process like the first function layer FL1. Accordingly, in the second functional layer FL2, the ends FL2_G1 and FL2 G2 may be provided which are disconnected in the groove parts 110_G1 and 110_G2. In addition, the second functional layer FL2 may be provided in a type that is disconnected in the second opening OP2. A portion of the evaporation material for providing the second function layer FL2 may be located in the second opening OP2 to be provided as the second layer L2. The second layer L2 may be an independent pattern separated from the second functional layer FL2. However, this is illustrated as an example, and according to an embodiment of the inventive concept, the second layer L2 may not be provided.

Then, as shown in FIG. 9K, the second electrode CE is provided. According to an embodiment, the second electrode CE may be provided through an evaporation process. Accordingly, in the second electrode CE, the ends CE_G1 and CE_G2 may be provided which are disconnected in the groove parts 110_G1 and 110_G2. In addition, the second electrode CE may be provided in a type that is disconnected in the second opening OP2. A portion of the evaporation material for providing the second electrode CE may be located in the second opening OP2 to be provided as the third layer L3. The third layer L3 may be an independent pattern separated from the second functional layer FL2. However, this is illustrated as an example, and according to an embodiment of the inventive concept, the third layer L3 may not be provided. In addition, the second electrode CE may be provided through a deposition process. In this case, the second electrode CE may be provided in a common integrated shape without being disconnected in the groove parts 110_G1 and 110_G2 or the second opening OP2.

Then, as shown in FIG. 9L, the first inorganic layer 141 may be provided. The first inorganic layer 141 may be provided through a deposition process. Accordingly, the first inorganic layer 141 may be provided in a common integrated shape without being disconnected in the groove parts 110_G1 and 110_G2 or the second opening OP2.

Then, as shown in FIG. 9M, the organic layer 142 may be provided. The organic layer 142 may be provided using an organic material in a solution state. The organic layer 142 may be provided by filling the first groove part 110_G1. Here, the organic layer 142 may be prevented by the dam part DM from being entering an area in which the second groove part 110_G2 and the hole are provided. Accordingly, the second groove part 110_G2 may be exposed from the organic layer 142.

Then, as shown in FIG. 9N, the second inorganic layer 143 may be provided. The second inorganic layer 143 may be provided through a deposition process. The second inorganic layer 143 may cover the top surface of the organic layer 142, and be also provided inside the second groove part 110_G2 exposed from the organic layer 142 between the groove parts 110_G1 and 110_G2. Accordingly, the second inorganic layer 143 may be provided in a common integrated shape on the entire surface of the substrate 110.

Then, as shown in FIG. 9O, the planarization layer YOC may be provided. The planarization layer YOC fills an area in which the hole is to be provided. The planarization layer YOC covers an area, which is not filled by the organic layer 142, to provide a planar surface on the top surface. According to an embodiment of the inventive concept, the planarization layer YOC is further included, and thus the first area A1 may also be provided with a planar surface having the same flatness as the organic layer 142.

Then, as shown in FIG. 9P, the sensor layer 200 and the anti-reflection layer 300 are sequentially provided, and then the display panel DP may be provided by providing the hole MH. The hole MH may be provided which penetrates through all the display layer 100, the sensor layer 200, and the anti-reflection layer 300. The hole MH may be provided by means of a laser, but is not limited thereto.

According to an embodiment of the inventive concept, there may be provided a display panel with relatively enhanced electrical reliability and relatively reduced consumption power.

In addition, according to an embodiment of the inventive concept, a manufacturing process of the display panel may be relatively simplified and a process cost may be relatively reduced.

While this invention has been described with reference to an embodiment thereof, it will be clear to those of ordinary skill in the art to which the invention pertains that various changes and modifications may be made to the described embodiments without departing from the spirit and technical area of the invention as defined in the appended claims and their equivalents. Thus, the scope of the inventive concept shall not be restricted or limited by the foregoing description, but be determined by the broadest permissible interpretation of the following claims, and their equivalents.

What is claimed is:

1. A display panel comprising:
a substrate comprising a first area having a first light transmissivity and a second area having a second light transmissivity lower than the first light transmissivity;
a plurality of pixel electrodes in the second area;
a blocking electrode on the substrate and spaced apart from the plurality of pixel electrodes;
a pixel definition layer at which first openings respectively exposing at least portions of the plurality of pixel electrodes and a second opening exposing at least a portion of the blocking electrode are defined;
a plurality of light emitting layers in the first respective openings;
a common electrode on the plurality of light emitting layers;
an encapsulation layer on the common electrode; and
a functional layer between the pixel definition layer and the common electrode,
wherein an area except for the portion exposed by the second opening in the blocking electrode contacts the pixel definition layer, and
the functional layer is connected in the first openings and is disconnected in the second opening.

2. The display panel of claim 1, wherein an inclination angle of a side surface defining the second opening in the pixel definition layer is in a range of 50 to 90 degrees.

3. The display panel of claim 2, wherein an inclination angle of a side surface defining the first openings in the pixel definition layer is smaller than that of the side surface defining the second opening in the pixel definition layer.

4. The display panel of claim 1, wherein the pixel definition layer comprises an organic material.

5. The display panel of claim 1, wherein the substrate further comprises:
a hole penetrating the first area; and
a groove part between the hole and the pixel definition layer, with a portion of a top surface being removed,
wherein the functional layer is disconnected in the groove part and the hole.

6. The display panel of claim 5, wherein the substrate comprises:
a base layer comprising an organic material;
a first intermediate barrier layer under the base layer and comprising an inorganic material; and
a second intermediate barrier layer on the base layer and comprising an inorganic material,
wherein the hole penetrates through the base layer, the first intermediate barrier layer, and the second intermediate barrier layer, and
the groove part penetrates the base layer and the second intermediate barrier layer and exposes the first intermediate barrier layer.

7. The display panel of claim 1, further comprising:
additional pixel electrodes in the first area,
wherein the first area comprises a transmission region and a light emitting region,
the additional pixel electrodes are spaced apart from the transmission region to be in the light emitting region, and
an inclination angle of a side surface adjacent to the transmission region in the pixel definition layer is larger than that of the side surface defining the first opening.

8. The display panel of claim 7, wherein the functional layer is disconnected in the transmission region.

9. The display panel of claim 1, wherein the second opening comprises a plurality of sub-openings spaced apart from each other.

10. The display panel of claim 9, wherein the blocking electrode is provided in plurality, the plurality of blocking electrodes respectively overlapping the sub-openings.

11. The display panel of claim 9, wherein the blocking electrode overlaps each of the sub-openings.

12. The display panel of claim 1, further comprising:
a laminated structure in the second opening,
wherein the laminated structure is separated from the functional layer and the common electrode.

13. The display panel of claim 12, wherein the laminated structure comprises a same material as any one of the functional layer and the common electrode.

14. The display panel of claim 1, wherein the encapsulation comprises at least one inorganic layer, and
the disconnected portions of the functional layer are covered with the inorganic layer.

15. A display panel manufacturing method comprising:
providing a substrate comprising a first sub-barrier layer comprising an inorganic material, a second sub-barrier layer on the first sub-barrier layer and comprising an inorganic material, and a base layer between the first sub-barrier layer and the second sub-barrier layer and comprising an organic material;
providing a plurality of pixel electrodes and a blocking electrode on the substrate;
providing a pixel definition layer in which a plurality of first openings respectively exposing the pixel electrodes are defined;
providing a sacrificial layer on the substrate;
providing a groove part on the substrate;
providing a second opening exposing the blocking electrode in the pixel definition layer;
removing the sacrificial layer;
providing a functional layer on the pixel definition layer;
providing a plurality of light emitting layers in the first openings;
providing a common electrode on the plurality of light emitting layers;
providing an encapsulation layer on the common electrode; and
providing a hole in the substrate,
wherein the second opening is provided after the plurality of first openings are provided, and
the second opening is provided through a same process as the groove part.

16. The display panel manufacturing method of claim 15, wherein
a plurality of opening parts are defined in the sacrificial layer,
the groove part is provided using a first opening part among the plurality of opening parts as a mask, and
the second opening is provided using a second opening part among the plurality of opening parts as a mask.

17. The display panel manufacturing method of claim 16, wherein providing the groove part comprises:
providing an opening in the second sub-barrier layer using the first opening part as the mask; and
etching the base layer using the first opening part as the mask.

18. The display panel manufacturing method of claim 17, wherein providing the second opening is simultaneously performed with the etching of the base layer.

19. The display panel manufacturing method of claim 18, wherein a size of the second opening is larger than that of the second opening part.

20. The display panel manufacturing method of claim 15, wherein the sacrificial layer comprises a transparent conductive oxide.

21. The display panel manufacturing method of claim 15, wherein the functional layer is provided through an evaporation process.

22. The display panel manufacturing method of claim 21, wherein the functional layer is disconnected in the groove part and the second opening to provide disconnected ends.

23. The display panel manufacturing method of claim 22, wherein
providing the encapsulation layer comprises depositing an inorganic material, and
the inorganic material is commonly provided along the disconnected ends, the groove part, and the second opening.
